(19) United States
(12) Patent Application Publication
(10) Pub. No.: US 2026/0171148 A1
(43) Pub. Date: Jun. 18, 2026

(54) MEMORY DEVICE WITH FULL PAGE DATA STORED ON DUAL STRINGS

(71) Applicant: Yangtze Memory Technologies Co., Ltd., Wuhan (CN)

(72) Inventors: Jialiang Deng, Wuhan (CN); Zhenjia Chen, Wuhan (CN)

(73) Assignee: Yangtze Memory Technologies Co., Ltd., Wuhan (CN)

(21) Appl. No.: 19/173,871

(22) Filed: Apr. 9, 2025

(30) Foreign Application Priority Data
Dec. 16, 2024 (CN) 202411855811.X

(51) Int. Cl. G11C 11/56; G11C 16/04; G11C 16/10; G11C 16/26

(52) U.S. Cl. CPC G11C 11/5628; G11C 11/5642; G11C 11/5671; G11C 16/0483; G11C 16/10; G11C 16/26

(57) ABSTRACT

A method of operating a memory device includes programming a first row of memory cells in a first string of the memory device based on a first portion of page data, programming a second row of memory cells in a second string of the memory device based on the first portion of the page data, programming the first row of memory cells in the first string of the memory device based on a second portion of the page data, and programming the second row of memory cells in the second string of the memory device based on a third portion of the page data.

### INCORPORATION BY REFERENCE

The present application claims priority to Chinese Patent Application No. 202411855811.X, filed on Dec. 16, 2024. The entire disclosure of the aforementioned application is incorporated herein by reference.

### TECHNICAL FIELD

The present application is related to memory devices and operation methods thereof.

### BACKGROUND

Flash memory is a low-cost, high-density, non-volatile solid-state storage medium that can be electrically erased and reprogrammed. Flash memory includes NOR flash memory and NAND flash memory. Various operations can be performed in a flash memory, such as read, program (write), and erase. For NAND flash memory, an erase operation can be performed at the block level, and a program operation or a read operation can be performed at the page level.

### SUMMARY

Aspects of the disclosure provide a method of operating a memory device. The method can include programming a first row of memory cells in a first string of the memory device based on a first portion of page data, programming a second row of memory cells in a second string of the memory device based on the first portion of the page data, programming the first row of memory cells in the first string of the memory device based on a second portion of the page data, and programming the second row of memory cells in the second string of the memory device based on a third portion of the page data.

In an embodiment, the first string of the memory device and the second string of the memory device belong to a same block of the memory device and share a page buffer. In an embodiment, a first memory cell in the first row of memory cells in the first string of the memory device and a second memory cell in the second row of memory cells in the second string of the memory device share a same page buffer circuit via a same bit line. In an embodiment, the first row of memory cells in the first string of the memory device and the second row of memory cells in the second string of the memory device are controlled by a same word line. In an embodiment, the page data includes 2N+1 pages, N being an integer greater than 1.

In an embodiment, the first portion of the page data includes 3 pages, the second portion of the page data includes 3 pages, and the third portion of the page data includes 3 pages. In an embodiment, the programming of the first row of memory cells in the first string of the memory device based on the first portion and the second portion of the page data includes performing a first pass of programming to set the first row of memory cells in the first string of the memory device to be in 3 states based on the first 3 pages of the page data, and performing a second pass of programming to set the first row of memory cells in the first string of the memory device to be in 24 states based on the second 3 pages of the page data. In an embodiment, the programming of the first row of memory cells in the first string of the memory device based on the first portion and the second portion of the page data is a 3-24-24 multi-pass process and further includes performing a third pass of programming to refine the 24 states of the first row of memory cells in the first string of the memory device.

In an embodiment, the method further including reading states of the first row of memory cells in the first string of the memory device. The programming the first row of memory cells in the first string of the memory device based on the second portion of the page data is based on the states of the first row of memory cells in the first string of the memory device.

Aspects of the disclosure provide another method of operating a memory device. The method can include performing a first read operation to a first row of memory cells in a first string of the memory device to obtain a first reading result of a first memory cell in the first row of memory cells in the first string of the memory device. The first reading result is stored in a first storage unit of a page buffer circuit. The method can further include performing a second read operation to a second row of memory cells in a second string of the memory device to obtain a second reading result of a second memory cell in the second row of memory cells in the second string of the memory device. The second reading result is stored in a second storage unit of the page buffer circuit. The method can further include determining a first bit based on the first reading result stored in the first storage unit of the page buffer circuit and the second reading result stored in the second storage unit of the page buffer circuit.

In an embodiment, a first read voltage is applied to the first row of memory cells in the first string of the memory device during the first read operation, and a second read voltage is applied to the second row of memory cells in the second string of the memory device during the second read operation. The first read voltage and the second read voltage take one of the following 3 read voltage level combinations: (i) the first read voltage and the second read voltage both are of a first read voltage level; (ii) the first read voltage has the first read voltage level, and the second read voltage has a second read voltage level; and (iii) the first read voltage has the second read voltage level; and the second read voltage has the first read voltage level. Corresponding to the 3 read voltage level combinations, 3 different pages are output from the memory device.

In an embodiment, 23 read voltage levels from RL1 to RL23 are used for reading operations in the memory device. In response to the first read voltage and the second read voltage both using RL8, a first one of the 3 different pages is output from the memory device. In response to the first read voltage using RL8 and the second read voltage using RL6, a second one of the 3 different pages is output from the memory device. In response to the first read voltage using RL16 and the second read voltage using RL8, a third one of the 3 different pages is output from the memory device.

In an embodiment, the method further comprising performing a third read operation to the first row of memory cells in the first string of the memory device to output a second page that is different from a first page that is one of the 3 different pages, and performing a fourth read operation to the second row of memory cells in the second string of the memory device to output a third page that is different from the first page and the second page. In an embodiment, depending on different read voltage level combinations, one of 3 different pages is output as the second page during the third read operation.

Aspects of the disclosure provide a memory device. The memory device can include a block that includes a first string and a second string sharing a page buffer. Each string has an array of memory cells having columns of memory cells and rows of memory cells. A peripheral circuit is coupled to the block and configured to program a first row of memory cells in the first string of the memory device based on a first portion of page data, program a second row of memory cells in the second string of the memory device based on the first portion of the page data, program the first row of memory cells in the first string of the memory device based on a second portion of the page data, and program the second row of memory cells in the second string of the memory device based on a third portion of the page data.

In an embodiment, the page data includes 2N+1 pages, the first portion of the page data includes 3 pages, the second portion of the page data includes N−1 pages, and the third portion of the page data includes N−1 pages, N being an integer greater than 1. In an embodiment, a first memory cell in the first row of memory cells in the first string of the memory device and a second memory cell in the second row of memory cells in the second string of the memory device share a same page buffer circuit via a same bit line.

In an embodiment, the page data includes 9 pages, and the peripheral circuit is configured to perform a first pass of programming to set the first row of memory cells in the first string of the memory device to be in 3 states based on the first 3 pages of the page data, and perform a second pass of programming to set the first row of memory cells in the first string of the memory device to be in 24 states based on the second 3 pages of the page data. In an embodiment, the peripheral circuit is further configured to perform a third pass of programming to refine the 24 states of the first row of memory cells in the first string of the memory device.

In an embodiment, the peripheral circuit includes a page buffer circuit in the page buffer. The page buffer circuit has a first storage unit, a second storage unit, and a cache storage unit. The peripheral circuit is configured to perform a first read operation to the first row of memory cells in the first string of the memory device to obtain a first reading result of a first memory cell in the first row of memory cells in the first string of the memory device. The first reading result is stored in the first storage unit. The peripheral circuit is further configured to perform a second read operation to the second row of memory cells in the second string of the memory device to obtain a second reading result of a second memory cell in the second row of memory cells in the second string of the memory device. The second reading result is stored in the second storage unit. The peripheral circuit is further configured to determine, a first bit based on the first reading result stored in the first storage unit and the second reading result stored in the second storage unit. The first bit is stored in the cache storage unit.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a block diagram of a system 100 according to some aspects of the present disclosure.

FIG. 2A illustrates a diagram of a memory card having a memory device according to some aspects of the present 10 disclosure.

FIG. 2B illustrates a diagram of a solid-state drive (SSD) having a memory device according to some aspects of the present disclosure.

FIG. 3 illustrates a schematic circuit diagram of a memory device 300 according to some aspects of the present disclosure.

FIG. 4 illustrates a side view of a cross-section of the block 301 according to some aspects of the present disclosure.

FIG. 5A illustrates some exemplary peripheral circuits according to some aspects of the present disclosure.

FIG. 5B illustrates exemplary threshold voltage distributions of memory cells in a program operation, according to some aspects of the present disclosure.

FIG. 6 illustrates a detailed block diagram of an exemplary structure of a page buffer according to some aspects of the present disclosure.

FIG. 7 shows threshold voltage distributions for the 3 bits/2 cells storage scheme.

FIG. 8 shows the mapping relationship between memory cell level combinations and 3-bits Gray codes at the left side of a table 800 and reading results from the paired memory cells when read levels are applied at the right side of the table 800.

FIG. 9 shows an example of pairing physical pages for storing whole-page data in an implementation of the N.5 bits scheme according to some aspects of the present disclosure.

FIG. 10 shows a page buffer circuit 1000 according to an implementation of the present disclosure.

FIG. 11 shows a multi-pass programming process 1100 according to an implementation of the present disclosure.

FIG. 12 shows a timing diagram of a program flow corresponding to the 3-24 2-pass programming process according to an implementation of the present disclosure.

FIG. 13 shows a mapping relationship between memory cell states and Gray codes of the 9 bits/2 cells storage scheme according to an implementation of the present disclosure.

FIG. 14 shows page buffer operation for reading first 3 data pages in the N.5 bits storage scheme according to an implementation of the present disclosure.

FIG. 15 shows read levels for 9 bits/2 cells storage scheme according to an implementation of the disclosure.

FIG. 16 shows read levels for 11 bits/2 cells storage scheme according to an implementation of the disclosure.

FIG. 17 shows, in a table 1700, mapping relationship of level (or state) combinations of paired cells, 3-bits data of first 3 pages, and reading results from paired cells in the 9 bits/2 cells storage scheme according to an implementation of the present disclosure.

FIG. 18A shows a multi-pass programming process 1800 according to an implementation of the present disclosure.

FIG. 18B shows a timing diagram of a program flow corresponding to the 3-48 2-pass programming process according to an implementation of the present disclosure.

FIG. 19 shows a process 1900 of operating a memory device according to an embodiment of the present disclosure.

FIG. 20 shows a process 2000 of operating a memory device according to an embodiment of the present disclosure.

### DETAILED DESCRIPTION OF EMBODIMENTS

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosure can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Multi-level cell technologies, such as triple-level cell (TLC) (3 bits per cell) or quad-level cell (QLC) (4 bits per cell), have been developed to increase storage capacity and reduce per-bit cost of memory devices. However, these technologies face challenges related to low reliability and suboptimal performance. To address the issue, the present disclosure introduces a fractional bits or N.5 bits technology, where the states of two paired cells are combined to store multiple bits. For example, this N.5 bits technology enables 9 bits/2 cells, 11 bits/2 cells, and other similar implementations.

In an example of 4.5 bits implementation, two memory cells from different strings in a NAND flash memory device are paired to store 9 bits. In a first pass of a program process, a first row of memory cells in an even string are programmed into 3 threshold voltage distributions based on data of pages 0 to 2. Then, a second row of memory cells in an odd string are programmed into 3 threshold voltage distributions also based on data of pages 0 to 2. In a second pass of the program process, the first row of memory cells in the even string are programmed into 24 threshold voltage distributions based on pages 3 to 5. Then, the second row of memory cells in the odd string are programmed into 24 threshold voltage distributions based on pages 6-8. As a result, 9 pages are stored in the two strings. Each string stores 4.5 pages.

In a read process for retrieving one of pages 0 to 2, a first read operation is performed on the even string. The output data from the even string is stored in first latches in a page buffer shared by the even string and the odd string. Subsequently, a second read operation is performed on the odd string. The output data from the odd string is stored in second latches in the same page buffer. The page buffer can include page buffer circuits. Each page buffer circuit corresponds to a bit line shared by the even string and odd string. Each page buffer circuit can include one first latch and one second latch. A logic operation with the input of the data stored in the first latch and the second latch generates one bit from each page buffer circuit. A final page can thus be read out from the even string and the odd string and output from the page buffer. It is understood that, while latches are described in some examples for storing reading results (output data from an even string and an odd string, or output data of a logic operation) in the present disclosure, any suitable storage units can be used in place of latches, such as flip-flops.

In the related art, half-bit technology is implemented, where half-page data (data having a size of a half page) are stored in a row of memory cells within a same string. The N.5 bits technology in the present disclosure handles page data with a full-page size (full-page data) because two rows of memory cells from two strings are employed to store full-page data. The full-page format is compatible with existing flash memory devices or memory controllers, thus reducing implementation cost. Moreover, in half-bit technology, additional logic circuits are required to process data output from a page buffer to calculate final half-page data. The N.5 bits technology in the present disclosure can employ existing logic circuits within the page buffer to determine final full-page data. Data path outside page buffer can be maintained without adding new logic circuits. This effectively reduces both implementation cost and die size.

The N.5 bits technology disclosed herein can be applied to implementations of 3.5 bits/cell, 4.5 bits/cell, 5.5 bits/cell, and the like. N can be a positive integer, such as 1, 2, 3, 4, 5, 6, and the like.

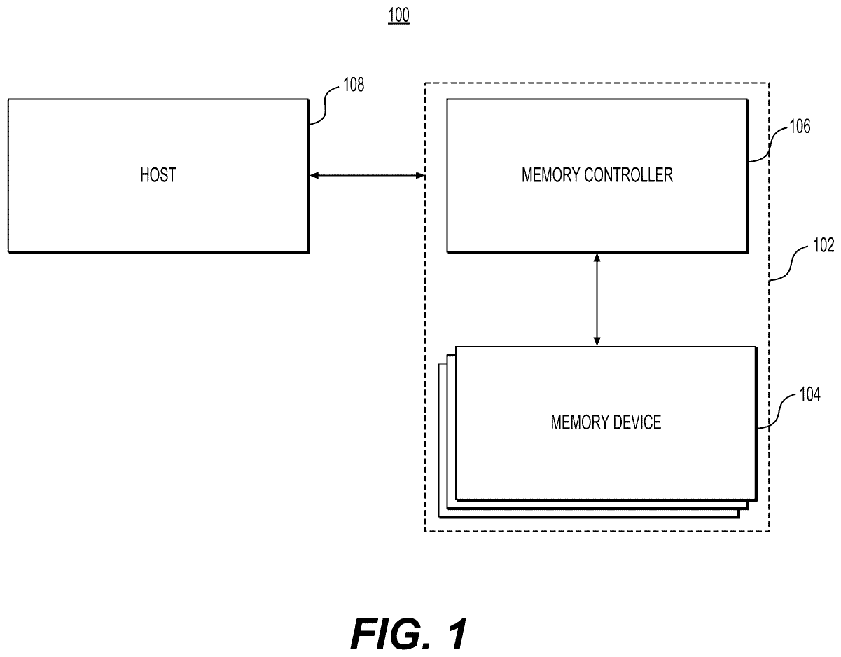

FIG. 1 illustrates a block diagram of a system 100 according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic devices having storage therein. As shown in FIG. 1, system 100 includes a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data to or from memory devices 104.

Memory device 104 can be any memory device disclosed in the present disclosure. As disclosed below in detail, memory device 104, such as a NAND Flash memory device, can perform program operations to program page data into paired memory cells of different strings. Multi-pass (or multi-step) program schemes can be employed during the program operations. Memory device 104 can also perform read operations to read page data out from paired memory cells of different strings.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment solid-stage drives (SSDs) or embedded multi-media-cards (eMMCs) used as data storage for mobile devices, such as smartphones, tablets, laptop computers, etc., and enterprise storage arrays.

Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, formatting memory device 104.

Memory controller 106 can communicate with an external device (e.g., host 108) according to a particular communication protocol. For example, memory controller 106 may communicate with the external device through at least one of various interface protocols, such as a USB protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

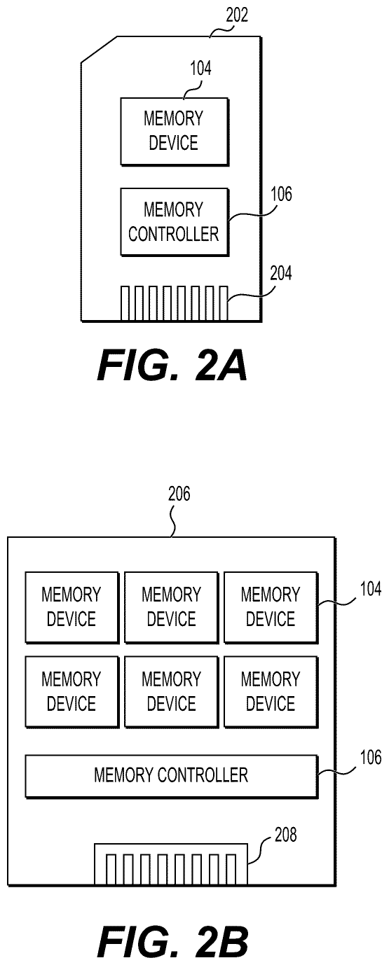

Memory controller 106 and one or more memory devices 104 can be integrated into various types of storage devices, for example, being included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 1). In another example as shown in FIG. 2B, memory controller 106 and multiple memory devices 104 may be integrated into a solid-state drive (SSD) 206. SSD 206 can further include an SSD connector 208 coupling SSD 206 with a host (e.g., host 108 in FIG. 1). In some implementations, the storage capacity and/or the operation speed of SSD 206 is greater than those of memory card 202.

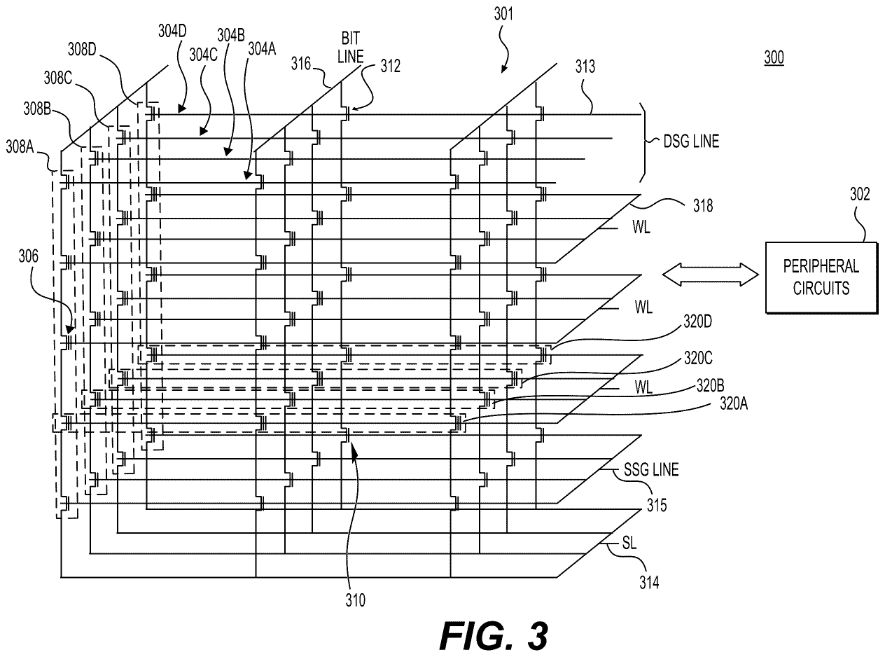

FIG. 3 illustrates a schematic circuit diagram of a memory device 300 according to some aspects of the present disclosure. Memory device 300 can be an example of memory device 104 in FIG. 1. Memory device 300 can include a memory cell array and peripheral circuits 302 coupled to the memory cell array. The memory cell array can be organized into planes. Each plane can include a collection of blocks. Each block can include multiple pages. An erasing operation can be performed at block level. Each page can include a collection of memory cells 306. FIG. 3 shows a block 301 as an example. The block 301 can be coupled with peripheral circuits 302.

The block 301 includes a plurality of strings 304A-304D. The strings 304A-304D can include even strings 304A and 304C and odd strings 304B and 304D. Each string 304A-304D can include an array of memory cells 306 of the block 301. It is understood that, while 4 strings are shown in FIG. 3, the block 301 can include any number of strings. Each string 304A-304D includes a plurality of rows and a plurality of columns of memory cells 306, such as the memory cell columns 308A-308D and the memory cell rows 320A-320D. One row of memory cells 306 corresponds to one page of memory cells according to some implementations.

The plurality of rows of memory cells 306 can be respectively coupled to word lines (WL) 318. As shown in FIG. 3, rows of memory cells 306 belonging to different strings but at the same lateral plane are connected to or share a same word line. For example, memory cell rows 320A-320D are connected to the same word line 318. The memory cells sharing a same word line form a horizontal layer of memory cells. Such a horizontal layer of memory cells is referred to as a cell layer. Each word line 318 can include a plurality of control gates (gate electrodes) at each memory cell 306 in a respective page and a gate line coupling the control gates. The plurality of columns of memory cells 306 can be respectively connected to bit lines 316. As shown in FIG. 3, memory cell columns 308A-308D are connected to or share the same bit line 316. The memory cells sharing a same bit line form a vertical layer of memory cells. Peripheral circuit 302 can be coupled to block 301 through bit lines 316 and word lines 318.

As shown in FIG. 3, each memory cell column, such as columns 308A-308D, can also include a source select gate (SSG) transistor 310 at its source end and a drain select gate (DSG) transistor 312 at its drain end. SSG transistor 310 and DSG transistor 312 can be configured to activate select memory cell column during read and program operations. In some implementations, the sources of memory cell columns in the same block 301 are coupled through a same source line (SL) 314, e.g., a common SL. In other words, all memory cell columns in the same block 301 have an array common source (ACS), according to some implementations. The drain of each memory cell column is coupled to the respective bit line 316 from which data can be read or written via an output bus (not shown), according to some implementations. In some implementations, each memory cell column is configured to be selected or deselected by applying a select voltage or a deselect voltage to the gate of respective DSG transistor 312 through one or more DSG lines 313 and/or by applying a select voltage or a deselect voltage to the gate of respective SSG transistor 310 through one or more SSG lines 315. In some implementations, memory cell columns in the same block 301 share the same SSG line 315.

In some implementations, each block 301 is the basic data unit for erase operations, i.e., all memory cells 306 on the same block 301 are erased at the same time. To erase memory cells 306 in a select block 301, source lines 314 coupled to select block 301 as well as unselect blocks in the same plane as select block 301 can be biased with an erase voltage (Vers), such as a high positive bias voltage (e.g., 20 V or more). Horizontal layers of memory cells 306 can be coupled through respective word lines 318 that select which row of memory cells 306 or which horizontal layer of memory cells is affected by read and program operations. A page of memory cells 306, such as each of pages 320A-320D is the basic unit for read and program operations.

The memory cells 306 can be NAND Flash memory cells. Each memory cell 306 can hold a continuous, analog value, such as an electrical voltage or charge, which depends on the number of electrons trapped within a region of memory cell 306. Each memory cell 306 can be either a floating gate type of memory cell including a floating-gate transistor or a charge trap type of memory cell including a charge-trap transistor. In some implementations, each memory cell 306 is a single level cell (SLC) that has two possible memory states (levels) and thus, can store one bit of data. For example, the first memory state “0” can correspond to a first range of threshold voltages, and the second memory state “1” can correspond to a second range of threshold voltages. In some implementations, each memory cell 306 is an xLC that is capable of storing more than a single bit of data in more than two memory states (levels). For example, the xLC may store two bits per cell (MLC), three bits per cell (TLC), or four bits per cell (QLC)). Each xLC can be programmed to assume a range of possible nominal storage values. For example, the MLC can be programmed to assume one of three possible programming levels from an erased state by writing one of three possible nominal storage values to the cell. A fourth nominal storage value can be used for the erased state.

In some implementations of N.5 bits technology, two memory cells are paired together to store multiple bits in the memory device 300. For example, seven bits data are stored in two memory cells 306 in a 7 bits/2 cells implementation. The memory cells 306 have a 12-level threshold voltage distribution. For example, nine bits data are stored in two memory cells 306 in a 9 bits/2 cells implementation. The memory cells 306 have a 24-level threshold voltage distribution. For example, eleven bits data are stored in two memory cells 306 in a 11 bits/2 cells implementation. The memory cells 306 have a 48-level threshold voltage distribution.

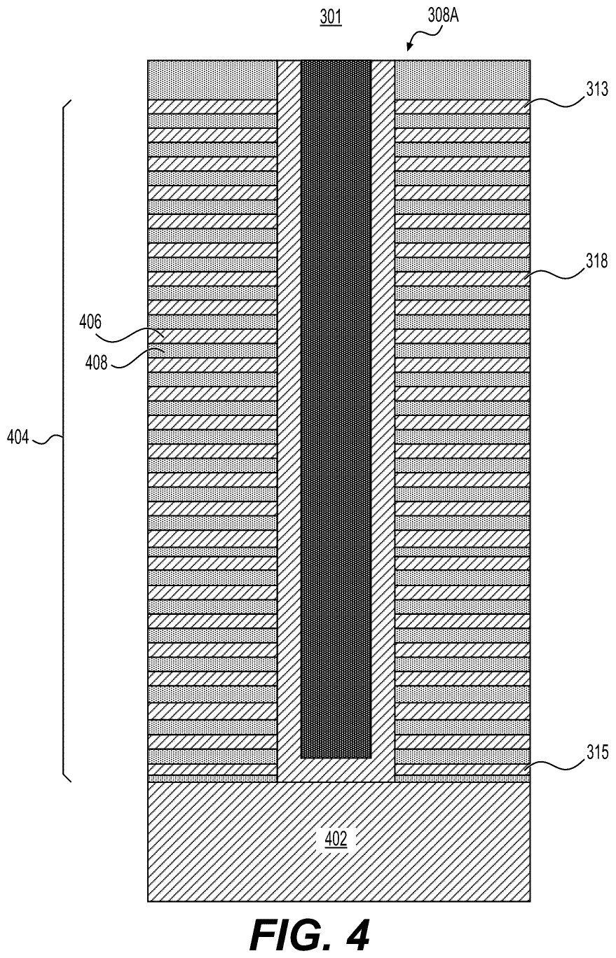

FIG. 4 illustrates a side view of a cross-section of the block 301 according to some aspects of the present disclosure. As shown in FIG. 4, memory cell column 308A can extend vertically through a memory stack 404 above a substrate 402. Substrate 402 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 404 can include interleaved gate conductive layers 406 and gate-to-gate dielectric layers 408. The number of the pairs of gate conductive layers 406 and gate-to-gate dielectric layers 408 in memory stack 404 can determine the number of memory cells 306 in the block 301. Gate conductive layer 406 can include conductive materials including, but not limited to, tungsten (W), cobalt (Co), copper (Cu), aluminum (Al), polysilicon, doped silicon, silicide, or any combination thereof. In some implementations, each gate conductive layer 406 includes a metal layer, such as a tungsten layer. In some implementations, each gate conductive layer 406 includes a doped polysilicon layer. Each gate conductive layer 406 can include control gates surrounding memory cells 306, the gates of DSG transistors 312, or the gates of SSG transistors 310, and can extend laterally as DSG line 313 at the top of memory stack 404, SSG line 315 at the bottom of memory stack 404, or word line 318 between DSG line 313 and SSG line 315.

As shown in FIG. 4, memory cell column 308A includes a channel structure extending vertically through memory stack 404. In some implementations, the channel structure includes a channel hole filled with semiconductor material(s) (e.g., as a semiconductor channel) and dielectric material(s) (e.g., as a memory film). It is understood that although not shown in FIG. 4, additional components of the block 301 can be formed including, but not limited to, gate line slits/source contacts, local contacts, interconnect layers, etc.

Referring back to FIG. 3, peripheral circuits 302 can be coupled to the block 301 through bit lines 316, word lines 318, source lines 314, SSG lines 315, and DSG lines 313. Peripheral circuits 302 can include any suitable analog, digital, and mixed-signal circuits for facilitating the operations of memory cells 306 in the block 301 by applying and sensing voltage signals and/or current signals to and from each select memory cell 306 through bit lines 316, word lines 318, source lines 314, SSG lines 315, and DSG lines 313. Peripheral circuits 302 can include various types of peripheral circuits formed using metal-oxide-semiconductor (MOS) technologies.

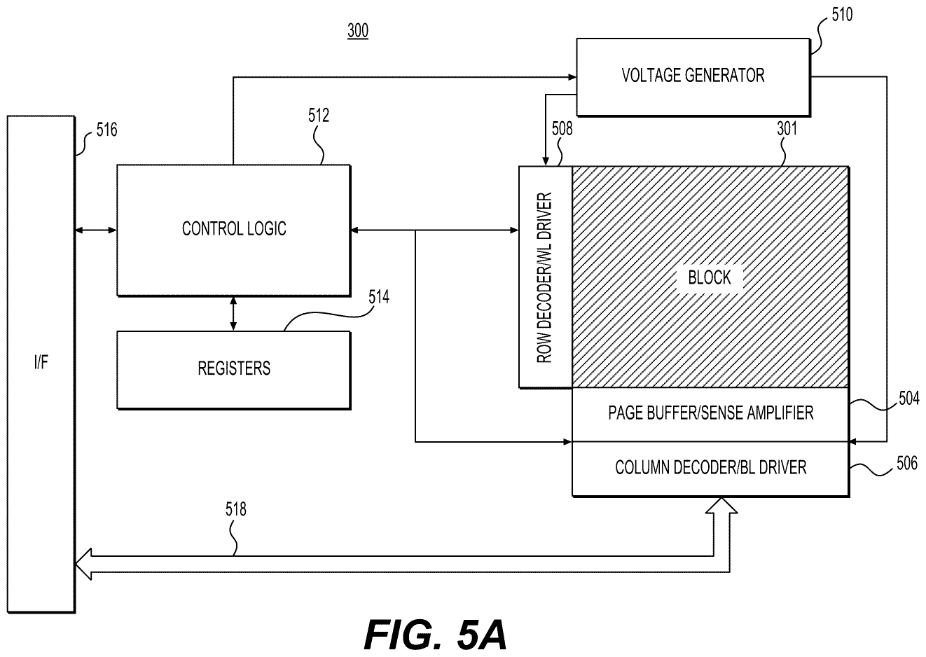

FIG. 5A illustrates some exemplary peripheral circuits including a page buffer/sense amplifier 504, a column decoder/bit line driver 506, a row decoder/word line driver 508, a voltage generator 510, control logic 512, registers 514, an interface (IF) 516, and a data bus 518. It is understood that in some examples, additional peripheral circuits not shown in FIG. 5A may be included as well.

Page buffer/sense amplifier 504 can be configured to sense (read) and program (write) data from and to memory cells 306 in the block 301 according to the control signals from control logic 512. In one example, page buffer/sense amplifier 504 may store multiple pages of program data to be programmed into one page 320A of memory cells 306. A page of program data can be referred to as a data page in the present disclosure. With respect to a data page, a page of memory cells can be referred to as a physical page. In another example, page buffer/sense amplifier 504 may verify programmed select memory cells 306 in each program/verify loop (cycle) in a program operation to ensure that the data has been properly programmed into memory cells 306 coupled to select word lines 318. In still another example, page buffer/sense amplifier 504 may also sense the low power signals from bit line 316 that represents a data bit stored in memory cell 306 and amplify the small voltage swing to recognizable logic levels in a read operation.

As described below in detail and consistent with the scope of the present disclosure, in program operations, page buffer/sense amplifier 504 can include a plurality of page buffer circuits respectively coupled to bit lines 316. Each page buffer circuit includes a set of storage units (that includes latches or flip-flops) for temporarily storing a piece of multi-bits data received from data bus 518 (converted from a piece of multi-bits raw data based on a Gray code). Each page buffer circuit provides the piece of multi-bits data to a corresponding select memory cell 306 through the corresponding bit line 316 in a program operation.

Column decoder/bit line driver 506 can be configured to be controlled by control logic 512 and select one or more memory cell columns by applying bit line voltages generated from voltage generator 510. Row decoder/word line driver 508 can be configured to be controlled by control logic 512 and select/deselect blocks of memory device 300 and select/deselect word lines 318 of respective block. Row decoder/word line driver 508 can be further configured to drive word lines 318 using word line voltages generated from voltage generator 510. In some implementations, row decoder/word line driver 508 can also select/deselect and drive SSG lines 315 and DSG lines 313 as well. Voltage generator 510 can be configured to be controlled by control logic 512 and generate the word line voltages (e.g., read voltage, program voltage, channel pass voltage, local voltage, verify voltage, etc.), bit line voltages, and source line voltages to be supplied to the block 301.

Control logic 512 can be coupled to each peripheral circuit described above and configured to control the operations of each peripheral circuit. Registers 514 can be coupled to control logic 512 and include status registers, command registers, and address registers for storing status information, command operation codes (OP codes), and command addresses for controlling the operations of each peripheral circuit. Interface 516 can be coupled to control logic 512 and act as a control buffer to buffer and relay control commands received from a memory controller (e.g., 106 in FIG. 1) and/or a host (e.g., 108 in FIG. 1) to control logic 512 and status information received from control logic 512 to the memory controller and/or the host. Interface 516 can also be coupled to column decoder/bit line driver 506 via data bus 518 and act as a data input/output (I/O) interface and a data buffer to buffer and relay the data to and from block 301.

FIG. 5B illustrates exemplary threshold voltage distributions of memory cells in a program operation, according to some aspects of the present disclosure. Each memory cell 306 can be set to one of multiple levels (or states) corresponding to a piece of multi-bits data. Each level (or state) can correspond to a threshold voltage (Vth) range of memory cells 306. FIG. 5B shows an example of TLCs. Memory cell 306 may be programmed into one of the 8 levels (or states), including one level of the erased state and 7 levels of the programmed states. Each level (or state) may correspond to a respective threshold voltage (Vth) range of memory cells 306. For example, the level corresponding to the lowest threshold voltage range (the left-most threshold voltage distribution in FIG. 5B) may be considered as level 0, the level corresponding to the second-lowest threshold voltage range (the second left-most threshold voltage distribution in FIG. 5B) may be considered as level 1, and so until level 7 corresponding to the highest threshold voltage range (the right-most threshold voltage distribution in FIG. 5B).

On the other hand, each level or state can correspond to a piece of multi-bits data that is to be stored in select memory cell 306. In some implementations, multi-bits data may be mapped to the multiple levels based on a Gray code. A Gray code (a.k.a., reflected binary code (RBC) or reflected binary (RB)) is an ordering of the binary numeral system such that two successive values differ in only one bit (binary digit). As an example, FIG. 5B shows a one-to-one mapping between 8 levels (L0 to L7) and 8 pieces of 3-bits data for TLCs. Each piece of 3-bits data may consist of three bits of binary values (b1, b2, and b3). Level 1 (L1) may correspond to a piece of 3-bits data having a value of 011. Level 7 (L7) may correspond to another piece of 3-bits data having a value of 101.

Also referring to FIG. 5A, in a program operation, page data having N pages (data pages) can be used to program a select row of memory cells 306 coupled to select word line 318 in string 304A. The page data has multiple pieces of N-bits data. Each piece of N-bits data includes N bits from the N pages. Peripheral circuits 302 can be configured to program a select row of memory cells 306 based on the page data. In some implementations, raw data (a.k.a. user data) is transmitted through data bus 518 to page buffer/sense amplifier 504, and page buffer/sense amplifier 504 is configured to convert the raw data into the page data to be programmed into a respective row of memory cells 306 based on a preset Gray code.

Based on the preset Gray code, which defines the mapping of each programmed level and a respective piece of N-bits data, control logic 512 is configured to send control signals (e.g., enable signals) to page buffer/sense amplifier 504 to allow page buffer/sense amplifier 504 to generate data pages for program operations, according to some implementations. N pages (a.k.a. portions) can be loaded into page buffer/sense amplifier 504. During the ongoing program operation, the current data pages can be temporarily stored in page buffer/sense amplifier 504. Page buffer/sense amplifier 504 can be configured to provide to each memory cell 306 coupled to selected word line 318 the corresponding piece of N-bits data through the corresponding bit line 316.

Also referring to FIG. 5A, in a read operation, page data having N pages stored in a selected row of memory cells 306 can be read out. The selected row of memory cells 306 is coupled to a selected word line 318. The page data can be read from the selected row of memory cells 306 through corresponding bit lines 316. For example, control logic 512 is configured to send control signals (e.g., enable signals) to page buffer/sense amplifier 504 (and any other suitable peripheral circuit) to allow page buffer/sense amplifier 504 to read the data page from the selected row of memory cells 306 and output the data page to I/F 516.

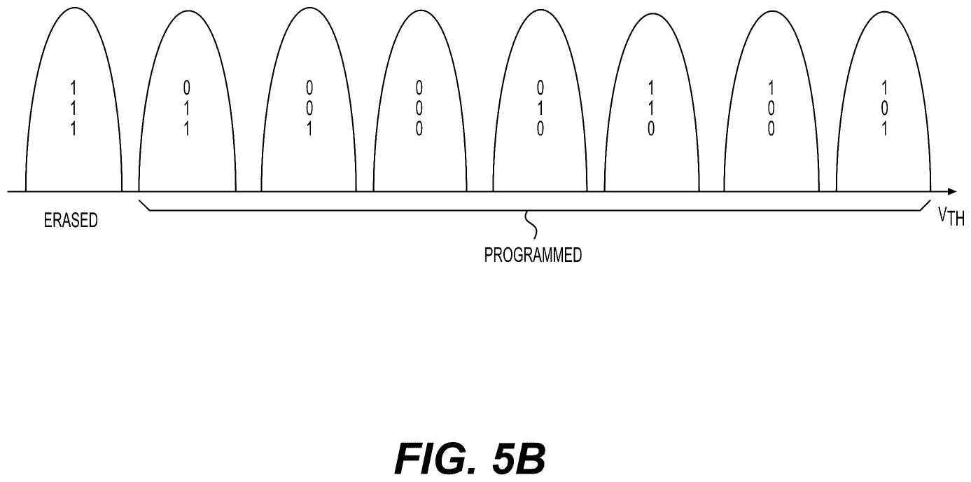

FIG. 6 illustrates a detailed block diagram of an exemplary structure of a page buffer (e.g., page buffer/sense amplifier 504), according to some aspects of the present disclosure. In some implementations, the page buffer in FIG. 6 includes a plurality of page buffer circuits 602. Each page buffer circuit 602 can be coupled to respective columns of memory cells 306 (e.g., memory cell columns 308A-308D) through a corresponding bit line 316. In a program operation, each page buffer circuit 602 is configured to temporarily store a piece of N-bits data that is used for programming a respective selected memory cell 306 (coupled to selected word line 318 and the corresponding bit line 316). All page buffer circuits 602 together can temporarily store the entire current page data (e.g., N data pages) that are used for programming a selected row of memory cells 306 (e.g., a physical page 320A of memory cells 306) coupled to selected word line 318 in the program operation. The corresponding piece of N-bits data may include N bits from the N data pages.

For example, for TLCs where N=3, each page buffer circuit 602 may be configured to temporarily store 3 bits of the current page data which correspond to one of the 8 levels. In a read operation, each page buffer circuit 602 is configured to temporarily store one or more bits of one or more respective data pages read from a respective selected memory cell 306 (coupled to selected word line 318 and the corresponding bit line 316).

In some implementations, each page buffer circuit 602 can include a plurality of storage units and a bias circuit 604. The plurality of storage units may include data storage units (D1, . . . , DN) 606, a cache storage unit 608, a bit line storage unit 610 (also referred to as bias voltage storage unit), and a sensing storage unit 612. For example, data storage units 606 can be configured to store bits of current page data for programming a respective memory cell 306 during a program operation. The cache storage unit 608 can be configured to store a bit of next page data to be programmed. To reduce the number of storage units and the size of page buffer circuit 602, the data storage units 606 and the cache storage unit 608 may be configured to be multi-purpose storage units in some implementations. For example, each or a portion of the data storage units 606 and the cache storage unit 608 can be configured to store both current page data or next page data in a time-division manner.

In some implementations, the number of cache storage unit 608 is more than one. In some implementations, the number of data storage units in each page buffer circuit 602 is configured to be at least the same as the number of bits in the piece of N-bits data used for programming the corresponding select memory cell 306. In some implementations, the number of data storage units 606 in each page buffer circuit 602 is configured to be N−1. The N−1 data storage units 606 and the cache storage unit 608 together are used for handling the N-bits data (in page data of N pages) used for programming the corresponding select memory cell 306.

In some implementations, sensing storage unit 612 and bit line storage unit 610 may be configured to store non-data page information, i.e., any information other than the data bits in a data page. For example, sensing storage unit 612 may be configured to store information indicative of whether the current operation performed by page buffer/sense amplifier 504 is a read operation or a program operation. In some implementations, sensing storage unit 612 may be a multipurpose storage unit that acts as both a sensing storage unit and a cache storage unit in a time-division manner. Bit line storage unit 610 may be configured to store the bias information of the respective bit line 316 coupled to page buffer circuit 602. In some implementations, bit line storage unit 610 may be a multipurpose storage unit that acts as both a bit line storage unit and a cache storage unit in a time-division manner.

In various implementations, each storage unit in page buffer circuit 602, including each data storage unit 606, cache storage unit 608, bit line storage unit 610, and sensing storage unit 612, may include any circuit that has two stable states for storing a single bit of data, such as a latch or a flip-flop. In one example, each of data storage units 606, cache storage unit 608, bit line storage unit 610, and sensing storage unit 612 may include a latch. In some implementations, page buffer circuit 602 has a 5-latch configuration that includes one cache latch, two data latches, one 3BL latch, and one sensing latch for a TLC memory device. In some implementations, page buffer circuit 602 has a 6-latch configuration that includes one cache latch, three data latches, one 3BL latch, and one sensing latch for a QLC memory device.

In a read operation, sensing storage unit 612 is coupled to a memory cell column. Sensing storage unit 612 is configured to sense data (e.g., a voltage level) stored in a memory cell 306. A cache storage unit 608 is coupled to interface 516 to receive or send data from or to interface 516. Thus, sensing storage unit 612 may be used to sense the data stored in the memory cell 306 and forward the sensed data to cache storage unit 608, causing cache storage unit 608 to output the sensed data to interface 516.

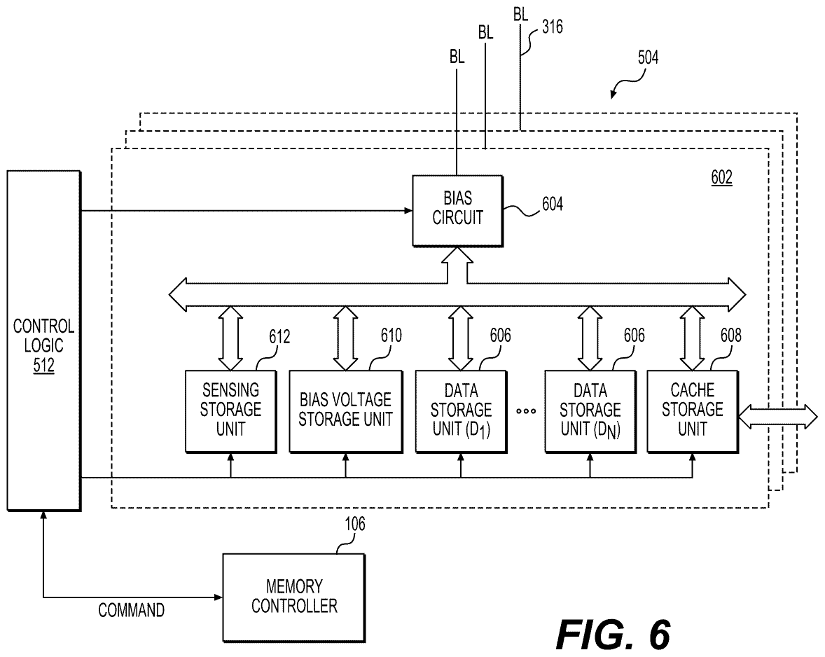

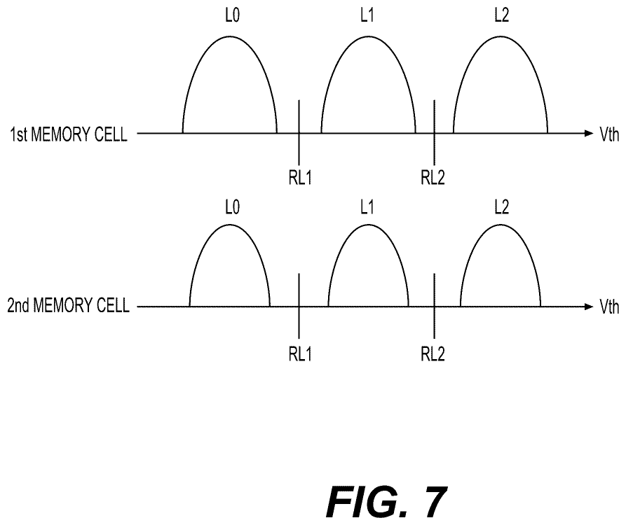

An implementation of 3 bits/2 cells storage scheme is explained below with reference to FIG. 7 and FIG. 8. In 3 bits/2 cells, a first memory cell from an even string and a second memory cell from an odd string are paired to store 3 bits. Each memory cell can be programmed to one of 3 levels (or 3 states). FIG. 7 shows threshold voltage distributions for the 3 bits/2 cells storage scheme. Each of the first memory cell and the second memory cell can possibly have 3 levels of threshold voltage distributions (or states), labeled as L0, L1, and L2. FIG. 8 shows the mapping relationship between memory cell level combinations and 3-bits Gray codes at the left side of a table 800. With two memory cells each having 3 levels, there are 9 level combinations shown in the first column of FIG. 8. Considering 3 bits are stored in the paired cells, 8 level combinations are used, while the level combination (L2, L0) (not shown) is not used. Each of the 8 level combinations is mapped to a piece of 3-bits data. Each bit of the 3-bits data belongs to a lower page, a middle page, or an upper page.

The right side of table 800 shows reading results from the paired memory cells when read levels are applied. FIG. 7 shows two read levels RL1 and RL2 applied to the paired memory cells during read operations. Read level is also referred to as read voltage level in the present disclosure. As shown in FIG. 8, during a read operation for reading a lower page, RL1 can first be applied to the first memory cell of the even string to obtain a first reading result. If the threshold voltage of the first memory cell is lower than RL1, the reading result is 0 (or 1). If the threshold voltage of the first memory cell is higher than RL1, the reading result is 1 (or 0). Subsequently, RL1 is applied to the second memory cell of the odd string to obtain a second reading result. Similarly, the reading result can be recorded as 0 or 1. Based on the reading results from the first memory cell and the second memory cell, a logic operation with input of the first and second reading results can be performed to output a bit for the lower page. For example, if both the reading results from the paired memory cells are 1, the output bit is 0. Otherwise, the output bit is 1 for other possible combinations of the reading results. A reading result is also referred to as a sensing result in the present disclosure.

For reading a middle page, read levels RL1 and RL2 can successively be applied to the first memory cell of the even string and the second memory cell of the odd string, respectively. In a similar way to reading the lower page, two reading results can be recorded as 0 or 1. A logical operation can be performed to output a bit for the middle page based on the reading results from the paired memory cells. If the reading results are (0, 0) or (1, 1), the output bit is 1. If the reading results are (1, 0) or (0, 1), the output bit is 0.

For reading an upper page, read levels RL2 and RL1 (which are switched compared with reading a middle page) can successively be applied to the first memory cell of the even string and the second memory cell of the odd string, respectively. Similarly, two reading results can be recorded as 0 or 1. A logical operation can be performed to output a bit for the upper page based on the reading results from the paired memory cells. If the reading results are (0, 0) or (1, 1), the output bit is 1. If the reading results are (1, 0) or (0, 1), the output bit is 0.

In an implementation of 7 bits/2 cells storage scheme, two memory cells from an even string and an odd string are paired to store 7 bits. Each memory cell is configured to have 12 possible levels. In an implementation of 9 bits/2 cells storage scheme, two memory cells from an even string and an odd string are paired to store 9 bits. Each memory cell is configured to have 24 possible levels. In an implementation of 11 bits/2 cells storage scheme, two memory cells from an even string and an odd string are paired to store 11 bits.

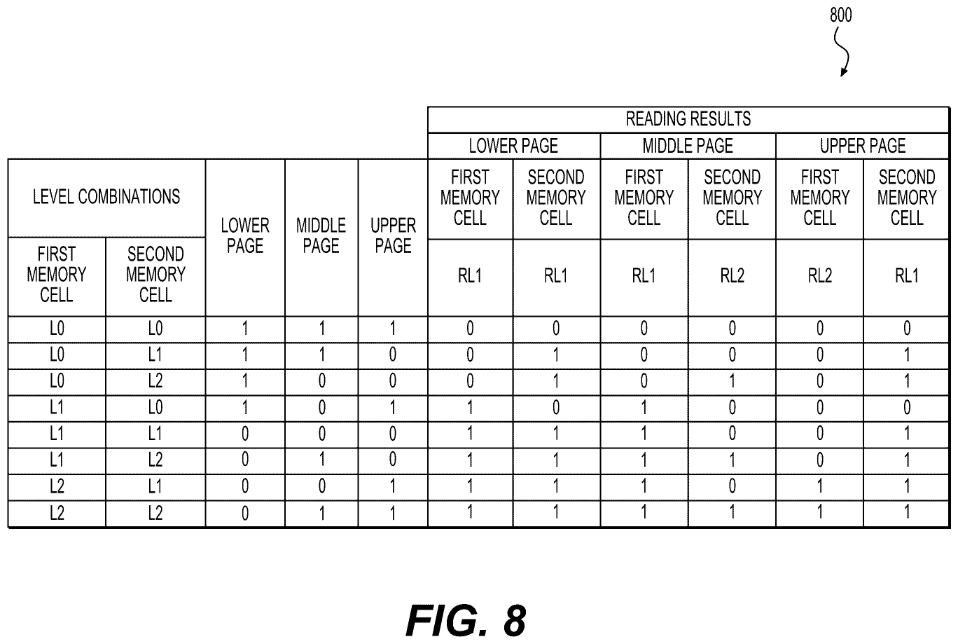

FIG. 9 shows an example of pairing physical pages for storing whole-page data in an implementation of the N.5 bits scheme. M cell layers from cell layer #1 to cell layer #M are shown in FIG. 9. M is a positive integer. Each cell layer includes multiple physical pages. Each physical page includes a row of memory cells. The physical pages in a same cell layer belong to different strings. For example, cell layer #1 is shown to include 6 physical pages 901-906 of memory cells which belongs to six different strings. Among the 6 physical pages, physical pages 901, 903, and 905 are even pages (labeled as page-even), and physical pages 902, 904, and 906 are odd pages (labeled as page-odd). Cell layer #M is shown to include 6 physical pages 911-916.

To implement the N.5 bits scheme, one even page and one odd page in a same memory layer but different strings are paired to store page data (that may include multiple data pages). For example, even page 901 in a first string is paired with odd page 902 in a second string to store first page data with full-page size, even page 903 in a third string is paired with odd page 904 in a fourth string to store second page data with full-page size, and even page 905 in a fifth string is paired with odd page 906 in a sixth string to store third page data with full-page size. For example, the paired even page and odd page can each have k memory cells and, when paired, provide k pairs of memory cells. Each such pair of memory cells includes a first memory cell from the even page and a second memory cell from the odd page. States of the pair of memory cells in combination are used to store page data. As full-page data is stored in two physical pages belonging to two different strings in the implement the N.5 bits scheme, such N.5 bits technology is said to be a full-page dual-string storage scheme.

In related art, a first cell and a second cell belonging to a same physical page in a same string are paired to store data. As a result, the size of data page is halved. For example, the number of the bits in such a half page is a half of the number of the memory cells in a physical page. Such technology can be said to be a half-page common-string storage scheme.

A full-page data format is more compatible with existing memory system than the half-page data format. For example, the memory controller and the peripheral circuits need less adjustment for implementing the full-page dual-string storage scheme than the half-page common-string storage scheme. Accordingly, the full-page dual-string storage scheme has technical advantages than the half-page common-string storage scheme.

In some implementations, each cell layer can have an odd number of physical pages. One physical page is left out without a counterpart to pair in the same cell layer. In such a configuration, a physical page from a cell layer can be paired with a physical page from another cell layer. For example, a last physical page in a first cell layer can be paired with a first physical page, a last physical page, or any physical page in a second cell layer.

More generally, to implement the N.5 bits technology, two paired physical pages can belong to a same cell layer but different strings, belong to a same string but different cell layers, or belong to different strings and different cell layers. Two paired physical pages can be adjacent or not adjacent to each other when belonging to a same string or a same cell layer.

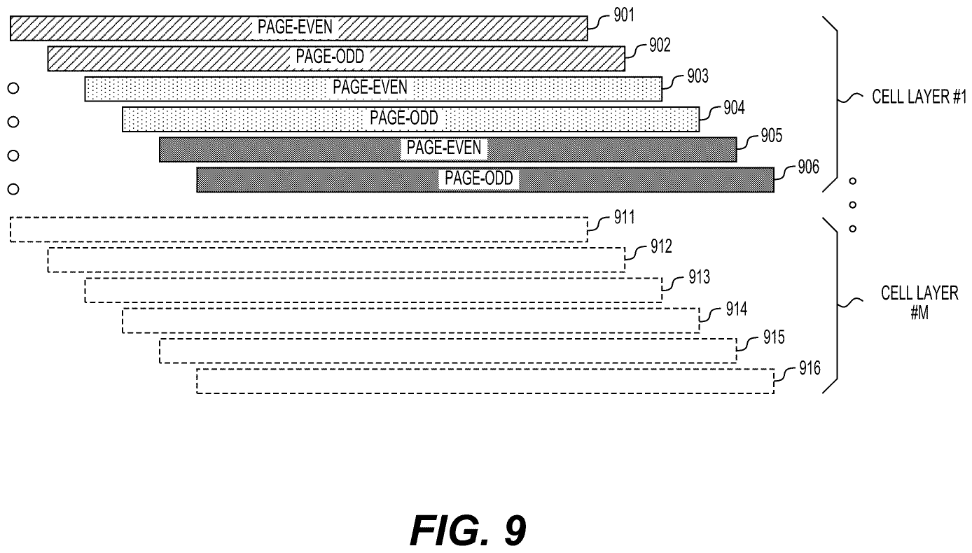

FIG. 10 shows a page buffer circuit 1000 according to an implementation of the present disclosure. The page buffer circuit 1000 can be configured to read a bit from two paired memory cells. The page buffer circuit 1000 can be a portion of the page buffer circuit 602 in FIG. 6. The page buffer circuit 1000 includes a bias circuit 1001, an even data storage unit 100, an odd data storage unit 1003, and a cache storage unit 1004. These elements are coupled to a sensing out (SO) node 1006 as shown in FIG. 10. The bias circuit 1001 is coupled to a bit line 1016.

The SO node 1006 can be any node in a connection line 1005 that connects to each of bias circuit 1001, even data storage unit 1002, odd data storage unit 1003, and cache storage unit 1004. A parasitic capacitor may be present in the connection line of the SO node 1006. When the SO node is pre-charged (or discharged), the parasitic capacitor in the connection line is pre-charged (or discharged). Under the control of control logic 512, for example, a sensing level (e.g., a sensing voltage level) is applied to a select memory cell coupled to page buffer circuit 1000 through bit line 1016 at a specific read time. A bias voltage is also applied to the bit line 1016 by bias circuit 1001 at the specific read time. If the SO node 1006 is discharged correspondingly (e.g., the higher the sensing level is, the faster the SO node is discharged), a bit value of 0 (a low voltage level) can be present at the SO node 1006. If the SO node 1006 is not discharged, a bit value of 1 (a high voltage level) can be present at the SO node 1006. Accordingly, a sensing result corresponding to the select memory cell can be determined based on the bit value of the SO node. Under the control of the control logic 512, even data storage unit 1002, odd data storage unit 1003, or cache storage unit 1004 can capture the sensing result present at the SO node 1006.

Based on the similar mechanism, under the control of the control logic 512, even data storage unit 1002 or odd data storage unit 1003 can output a bit value at the SO node 1006 by discharging or not discharging the SO node 1006. The bit value at the SO node 1006 is captured by the cache storage unit 1004. Or, even data storage unit 1002 and odd data storage unit 1003 can output two bit values at the SO node 1006 at the same time. For example, if one of the two bit values is 0, meaning the SO node 1006 is discharged, a bit value of 0 will be present at the SO node 1006. If both of the two bit values are 1, meaning the SO node is not discharged, a bit value of 1 will be present at the SO node 1006. Cache storage unit 1004 can similarly capture the bit value at the SO node 1006.

The operation of the page buffer circuit 1000 for the N.5 bits technology is explained with reference to the example of 3 bits/2 cells storage scheme shown in FIG. 8.

As shown in FIG. 8, two paired memory cells store 3 bits. To read a bit from two paired memory cells, two read operations can be performed. In a first read operation, a first reading result can be obtained from the first memory cell at the SO node 1006 and stored in the even data storage unit 1002. In a second read operation, a second reading result can be obtained from the second memory cell at the SO node 1006 and stored in the odd data storage unit 1003. For example, FIG. 8 shows 8 level combinations of a first memory cell and a second memory cell. The first and second memory cells can be paired and coupled to the bit line 1016. Each level combination represents a piece of 3-bits data belonging to a lower page, a middle page, and an upper page.

Taking reading the lower page as an example, in the first read operation, the read level RL1 is applied to the first memory cell, and a first reading result can be obtained at the SO node 1006 and stored to the even data storage unit 1002. Similarly, in the second read operation, the read level RL2 is applied to the second memory cell, and a second reading result can be obtained at the SO node 1006 and stored to the odd data storage unit 1003.

After the second read operation, a logic operation can be performed based on the first and second reading results to output a bit of the lower page. For example, even data storage unit 1002 and odd data storage unit 1003 include first latch and second latch respectively for storing the first and second reading results respectively. Also, even data storage unit 1002 and odd data storage unit 1003 each include first logic circuit and second logic circuit, respectively. Under the control of control logic 512, even data storage unit 1002 can output a first bit value (a low or high voltage level) at the SO node 1006 from the first logic circuit with an input of the first reading result at the first latch. Similarly, odd data storage unit 1003 can output a second bit value (a low or high voltage level) at the SO node 1006 from the second logic circuit with an input of the second reading result at the second latch. At the SO node 1006, an output result based on both the output bit values from the even data storage unit 1002 and odd data storage unit 1003 is present. Under the control of control logic 512, cache storage unit 1004 can capture the output result at the SO node 1006 and store the output result in a latch as the bit of the lower page. The bit of the lower page can subsequently be output from the page buffer circuit 1000. In the above logic operation, the first logic circuit of even data storage unit 1002, the second logic circuit of odd data storage unit 1003, and the SO node 1006 together function as a logic circuit for the logic operation.

For reading a data page from two paired physical pages, each pair of memory cells can be coupled to and share a page buffer circuit like the page buffer circuit 1000. During the first read operation and the second read operation, first reading results from the first physical page and second reading results from the second physical page can be obtained. After the respective logic operations, a full data page can be output from the page buffer circuits 1000.

In the half-page common-string technology, two reading results from two paired memory cells are stored in two different page buffer circuits because the two paired memory cells belong to a same string and cannot share a same page buffer circuit. To perform a necessary logic operation based on the reading results from the two different page buffer circuit, additional logic circuits have to be added to process outputs from two page buffer circuits, which increases hardware cost and die size. In implementing the full-page dual-string technology, the logic circuit used for the logic operation is already included in a page buffer circuit and can be suitably adjusted or configured to implement related functions without adding new logic circuit. Thus, the full-page dual-string technology avoids introducing new hardware and increasing die size of the peripheral circuits 302.

For reading the middle page and the upper page in the FIG. 8 examples, different read levels can be applied to the respective memory cells during the first and second read operations. Generally, for reading a bit value from two paired memory cells, the first reading operation to the first memory cell or the second reading operation to the second memory cell may apply one or multiple read levels at one or multiple reading times. One or multiple sensing results can be present at the SO node 1006 at the one or multiple reading times. Even data storage unit 1002 or odd data storage unit 1003 can be accordingly updated by the one or multiple sensing results. A final reading result of the first memory cell or the second memory cell can be stored in a respective data storage unit. Thereafter, a logic operation can be performed based on the reading results to output a bit.

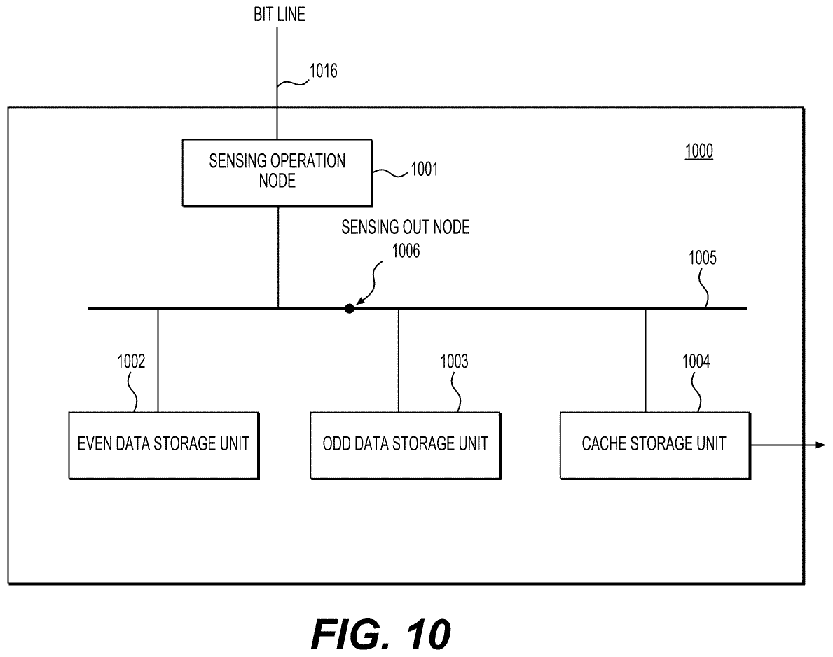

FIG. 11 shows a multi-pass programming process 1100 according to an implementation of the present disclosure. The process 1100 can be performed for programming paired memory cells in the 9 bits/2 cells storage scheme. The process 1100 is a 3-24 2-pass programming process that includes a first programing pass and a second programing pass. For example, the paired memory cells include a first memory cell of an even string and a second memory cell of an odd string. Nine data pages, from page 0 to page 8, are used to program the paired memory cells. For example, a process for programming the paired memory cells can include the following stages.

In a first stage, the first programming pass shown in FIG. 11 can be performed to program the first memory cell. For example, the first memory cell is programmed from an initial level (an erased state) S0 to one of 3 intermediate levels (or states/distributions) S0′, S8′, and S16′. The first programming pass can be based on 3-bits data from page 0, page 1, and page 2. Similar to what is shown in FIG. 8, where a voltage level (L0, L1, or L2) of the first or second memory cell can be determined based on 3-bits data, the voltage level (one of S0′, S8′, and S16′) of FIG. 11 can be determined based on the 3-bits data. In a second stage, the first programming pass shown in FIG. 11 can be performed to program the second memory cell in a similar way based on the same 3-bits data used for programming the first memory cell.

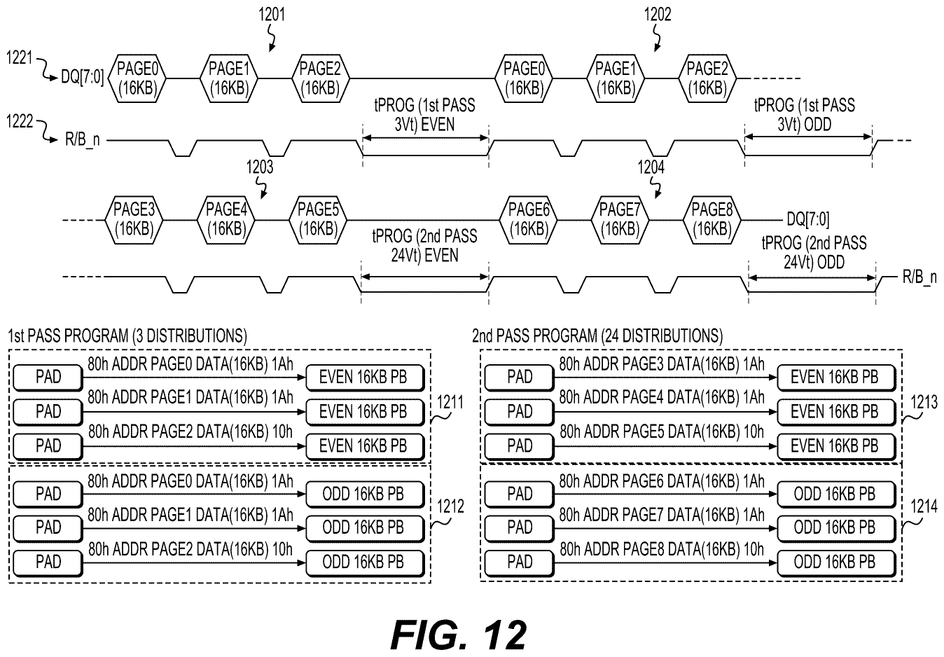

In a third stage, the second programming pass shown in FIG. 11 can be performed to program the first memory cell. The first memory cell is programmed from the intermediate level to one of 24 final levels (or states/distributions) from S0 to S23. The second programming pass can be based on 3-bits data from page 3, page 4, and page 5. The second programming pass can also be based on the intermediate level the memory cell previously is programmed in. In one implementation, during the second programming pass, the intermediate level of the memory cell is first read from the memory cell. Respective bits values (e.g., first 2 bits of a 5-bit Gray code in FIG. 13) indicating the intermediate level can be stored in data storage units in a page buffer circuit. Based on the 2 bits indicating the intermediate level and the 3 bits of the second set of 3 data pages (pages 3-5), a target level (one of the 24 final levels) can be determined, for example, according to FIG. 13. In a fourth stage, the second programming pass shown in FIG. 11 can be performed to program the second memory cell in a similar way but based on 3-bits data from page 6, page 7, and page 8.

In some implementations, the multi-pass programming pass 1100 may further include a third programming pass. During the third programming pass, the 24 distributions of memory cells can further be refined. For example, gaps between the distributions can be optimized (for example, broadened), and a larger read margin can be achieved. In such a situation, the process 1100 is a 3-24-24 3-pass programming process.

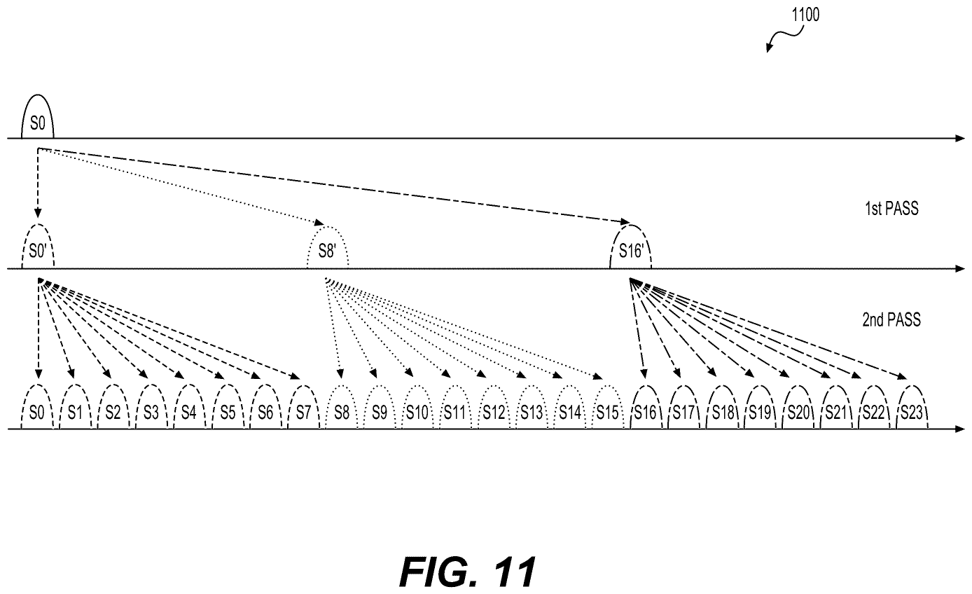

FIG. 12 shows a timing diagram of a program flow corresponding to the 3-24 2-pass programming process according to an implementation of the present disclosure. Four data transmission periods 1201-1204 are shown along a signal line 1222. Also shown along the signal line 1222 is a page data flow 1221 with an 8-bit data width between a memory controller and a memory device. The signal line 1222 indicates ready/busy (R/B) status of the memory device for receiving page data from the memory controller. As shown, during the first data transmission period 1201, first page data (page 0, page 1, and page 2) with a full-page size of 16 kB are sequentially transmitted from the memory controller to the memory device. Thereafter, a first programming pass to program first memory cells in an even physical page in an even string is performed. The first memory cells are programmed to the 3 intermediate levels (or 3 threshold voltage (Vt) distributions) S0′, S8′, and S16′, shown in FIG. 11.

During the second data transmission period 1202, the same first page data (page 0, page 1, and page 2) are sequentially transmitted. Thereafter, a first programming pass to program second memory cells in an odd physical page in an odd string is performed. Similarly, the second memory cells are programmed to the 3 intermediate levels (or 3 threshold voltage (Vt) distributions).

During the third data transmission period 1203, second page data (page 3, page 4, and page 5) are sequentially transmitted. Thereafter, a second programming pass to program first memory cells in the even physical page is performed. The first memory cells are programmed to 24 final levels (or 24 threshold voltage (Vt) distributions). During the fourth data transmission period 1204, third page data (page 6, page 7, and page 8) are sequentially transmitted. Thereafter, a second programming pass to program second memory cells in the odd physical page is performed. Similarly, the second memory cells are programmed to 24 final levels (or 24 threshold voltage (Vt) distributions).

Page data reception operations 1211-1214 from input pads to a page buffer (PB) are shown below the timing diagram in FIG. 12. The page data reception operations 1211-1214 correspond to the 4 data transmission periods 1201-1204, respectively. The page data reception operation 1211 includes sequential data receptions of three 16 kB data pages (page 0, page 1, and page 2) at the page buffer for the first-pass programming of the even string. The page data reception operation 1212 includes sequential data receptions of three 16 kB data pages (page 0, page 1, and page 2) at the page buffer for the first-pass programming of the odd string. The page data reception operation 1213 includes sequential data receptions of three 16 kB data pages (page 3, page 4, and page 5) at the page buffer for the second-pass programming of the even string. The page data reception operation 1214 includes sequential data receptions of three 16 kB data pages (page 6, page 7, and page 8) at the page buffer for the second-pass programming of the odd string. In the page data reception operations 1211-1214, full-page data with a size of 16 kB is transmitted.

In the programming process of 9 bits/2 cells storage scheme shown in FIG. 11 and FIG. 12, three data pages (pages 0-2) are programmed in paired memory cells in an even string and an odd string, 3 data pages (pages 3-5) are programmed in the even string, and 3 data pages (pages 6-8) are programmed in the odd string. Accordingly, the data page distribution among the physical pages or strings is represented as 3-3-3.

For a programming process of 11 bits/2 cells storage scheme, the data page distribution of 11 data pages among physical pages or strings can be 3-4-4 according to an implementation of the disclosure. Three data pages (pages 0-2) are programmed in paired memory cells in an even string and an odd string, 4 data pages (pages 3-6) are programmed in the even string, and 4 data pages (pages 7-10) are programmed in the odd string.

A 3-48 2-pass programming scheme can be employed for the 11 bits/2 cells storage scheme according to an implementation of the disclosure. First memory cells in an even string and second memory cells in an odd string are paired for storing 11 data pages. During the programming process of 11 bits/2 cells storage scheme, a first-pass programming can be performed to program the first memory cells in the even string based on pages 0-2. The first memory cells are programmed to 3 intermediate levels (or states) S0′, S16′, and S32′. Another first-pass programming can be performed to program the second memory cells in the odd string based on pages 0-2. The second memory cells are also programmed to 3 intermediate levels (or states) S0′, S16′, and S32′. Thereafter, a second-pass programming can be performed to program pages 3-6 to the first memory cells in the even string. The first memory cells are programmed from the 3 intermediate levels to 48 final levels (or states) from S0 to S47. Another second-pass programming can be performed to program pages 7-10 to the second memory cells in the odd string. The second memory cells are programmed from the 3 intermediate levels to 48 final levels (or states) from S0 to S47.

Similarly, for a programming process of 7 bits/2 cells storage scheme, the data page distribution among physical pages or strings can be 3-2-2 according to an implementation of the disclosure. A 3-12 2-pass programming scheme can be employed for the 7 bits/2 cells storage scheme according to an implementation of the disclosure.

Generally, for a programming process of N.5 bits/cell storage scheme, the data page distribution among physical pages or strings can be 3-(N−1)-(N−1). For example, the page data is stored in two paired strings: an even string and an odd string. The page data includes 2N+1 pages (data pages). The first portion of the page data includes 3 pages (data pages) that are stored in paired memory cells in the even string and the odd string. The second portion of the page data includes N−1 pages (data pages) that are stored in the even string. The third portion of the page data includes N−1 pages (data pages) that are stored in the odd string. Accordingly, the programming scheme can be a 3-(3*2^{(N-1)}) scheme. In such a programming scheme, memory cells in a physical page can first be programmed into 3 intermediate levels (or states/distributions) in a first pass and then 3*2^{(N-1)} final levels in a second pass. A fine pass may additionally be performed.

In some implementations, a programming process of N.5 bits/cell storage scheme follows the following order: first-pass programming of first physical page, first-pass programming of second physical page, second-pass programming of first physical page, and second-pass programming of second physical page. In other implementations, a programming process of N.5 bits/cell storage scheme follows a different order: first-pass programming of first physical page, second-pass programming of first physical page, first-pass programming of second physical page, and second-pass programming of second physical page.

FIG. 13 shows a mapping relationship between memory cell states and Gray codes of the 9 bits/2 cells storage scheme according to an implementation of the present disclosure. As shown, each state (one of S0-S23) corresponds to a 5-bits binary code. The first 2 bits of the 5-bits binary code are associated with two factors: the first 3 data pages (pages 0-2) and a string index (or physical page index, or paired memory cell index). For example, for a first memory cell in two paired memory cells having indices #0 and #1, the first 2 bits of the respective binary code can be determined based on the 3-bits data programmed into the paired memory cells and the memory cell index #1 of the first memory cell. Such a relationship is similar to the mapping relationship between the level combinations and the 3 data pages shown in FIG. 8. By replacing the level of L0, L1, L2 in FIG. 8 with a 2-bits value of (1, 1), (0, 1), (0, 0), respectively, FIG. 8 can show the relationship between the 2-bits value of a first or second memory cell and the 3-bits data of pages 0-3 (the lower, middle, and upper pages).

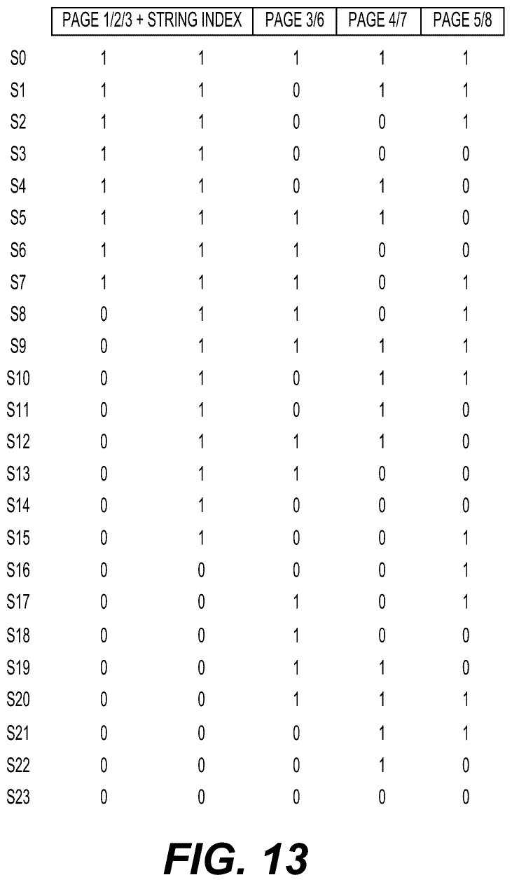

FIG. 14 shows page buffer operation for reading first 3 data pages in the N.5 bits storage scheme according to an implementation of the present disclosure. For example, the first 3 data pages (pages 0-2) are stored in two paired physical pages in an even string and an odd string. During a process of reading one of the first 3 data pages, a read command (for example, 00h-ADD (data page 0, 1, or 2)-30h) can be transmitted from a memory controller to a memory device. The read command can provide address information of the target data page. Accordingly, the paired physical pages can be located. A first read operation can performed by peripheral circuits of the memory device to a row of k memory cells in the even string. The full-page data (full-page reading results) can thus be obtained from the even string and stored in a page buffer.

The page buffer can include k number of page buffer circuits corresponding to k number of memory cells in a physical page. Each page buffer circuit can include a first data storage unit 1401, a second data storage unit 1402, and a cache storage unit 1404. Those elements 1401/1402/1404 can be coupled to an SO node 1403. The even-string full-page data can be stored in the respective first storage units 1401 in the page buffer. A second read operation can subsequently be performed by the peripheral circuits of the memory device to a row of k memory cells in the odd string. The odd-string full-page data (full-page reading results) can be stored in the respective second storage units 1402 in the page buffer.

Thereafter, in the respective page buffer circuit, a logic operation can be performed based on reading results (2 bits) from the respective first data storage unit 1401 and the respective second storage unit 1402. As a result, a bit of the respective page data can be present, for example, at the SO node 1403. The respective cache storage unit 1404 can capture the bit of the respective page data and output it from the page buffer circuit, for example, via a pad 1405. From the page buffer, full-page page data can be output.

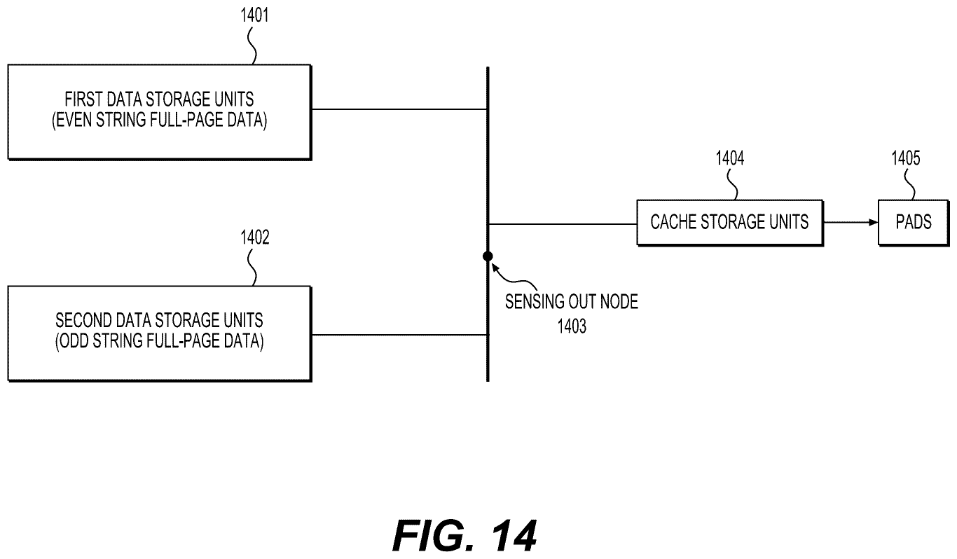

FIG. 15 shows read levels for 9 bits/2 cells storage scheme according to an implementation of the disclosure. Paired memory cells of 9 bits/2 cells storage scheme can have 24 threshold voltage distributions (or 24 states). Accordingly, there can be 23 read levels from RL1 to RL23 at positions pointed by arrows shown in FIG. 15. To read the first 3 data pages (page 0, page 1, and page 2), respective read operations can be performed to paired memory cells (first memory cell and second memory cell) with read voltages RL8 or RL16. For example, to read page 0, RL8 can be applied to the first memory cell in a first read operation and to the second memory cell in a second read operation. To read page 1, RL8 can be applied to the first memory cell in a first read operation, and RL16 can be applied to the second memory cell in a second read operation. To read page 2, RL16 can be applied to the first memory cell in a first read operation, and RL8 can be applied to the second memory cell in a second read operation. A logic operation can be performed based on the two reading results from the first read operation and the second read operation to output a bit of the respective data page (one of pages 0-2).

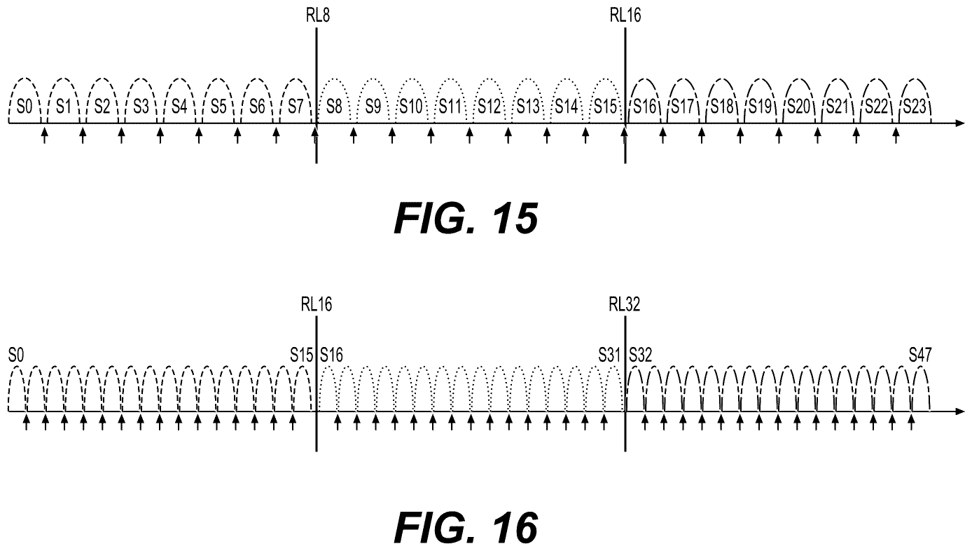

FIG. 16 shows read levels for 11 bits/2 cells storage scheme according to an implementation of the disclosure. Paired memory cells of 11 bits/2 cells storage scheme can have 48 threshold voltage distributions (or 48 states). Accordingly, there can be 47 read levels from RL1 to RL47 at positions pointed by arrows shown in FIG. 16. To read the first 3 data pages (page 0, page 1, and page 2), respective read operations can be performed to paired memory cells (first memory cell and second memory cell) with read voltages RL16 or RL32. For example, to read page 0, RL16 can be applied to the first memory cell in a first read operation and to the second memory cell in a second read operation. To read page 1, RL16 can be applied to the first memory cell in a first read operation, and RL32 can be applied to the second memory cell in a second read operation. To read page 2, RL32 can be applied to the first memory cell in a first read operation, and RL16 can be applied to the second memory cell in a second read operation. Similarly, a logic operation can be performed based on the two reading results from the first read operation and the second read operation to output a bit of the respective data page (one of pages 0-2).

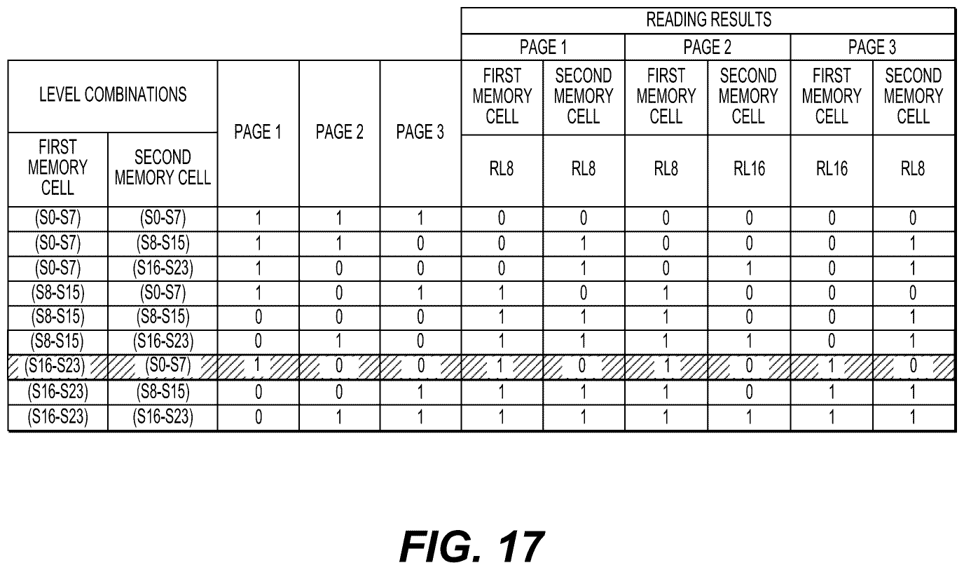

FIG. 17 shows, in a table 1700, mapping relationship of level (or state) combinations of paired cells, 3-bits data of first 3 pages, and reading results from paired cells in the 9 bits/2 cells storage scheme according to an implementation of the present disclosure. Based on the two reading results from the first memory cell and the second memory cell for reading page 0, a NAND logic operation can be performed to determine a bit of page 0. Based on the two reading results from the first memory cell and the second memory cell for reading page 1 or 2, an XNOR logic operation can be performed to determine a bit of page 1 or 2. The row of level combination ((S16-S23), (S0-S7)) is not used in table 1700.

For reading data pages other than the first 3 data pages in N.5 bits storage scheme, a read operation can be performed to a physical page. The read levels for the read operation can be determined according to Gray code used in the N.5 bits storage scheme. For example, in a 9 bits/2 cells storage scheme, pages 3-5 are programmed into an even physical page in an even string, and pages 6-8 are programmed into an odd physical page in an odd string. The Gray codes of FIG. 13 are employed for the 9 bits/2 cells storage scheme. For example, in response to receiving a read command 00h-ADD (page 3)-30h for reading page 3, multiple read levels RL1, RL5, RL10, RL12, RL14, and RL17 can be applied to memory cells in the even physical page at multiple sensing times by peripheral circuits. Sensing circuits in a page buffer coupled to the even physical page can perform sensing operations at the multiple sensing times to obtain bit values of page 3. For reading page 6, the same set of multiple read levels can be applied to the odd physical page. For reading pages 4 and 7, multiple read levels RL2, RL4, RL9, RL13, and RL19 can be applied to the even or odd physical string. For reading pages 5 and 8, multiple read levels RL3, RL7, RL11, RL15, RL18, and RL20 can be applied to the even or odd physical string.

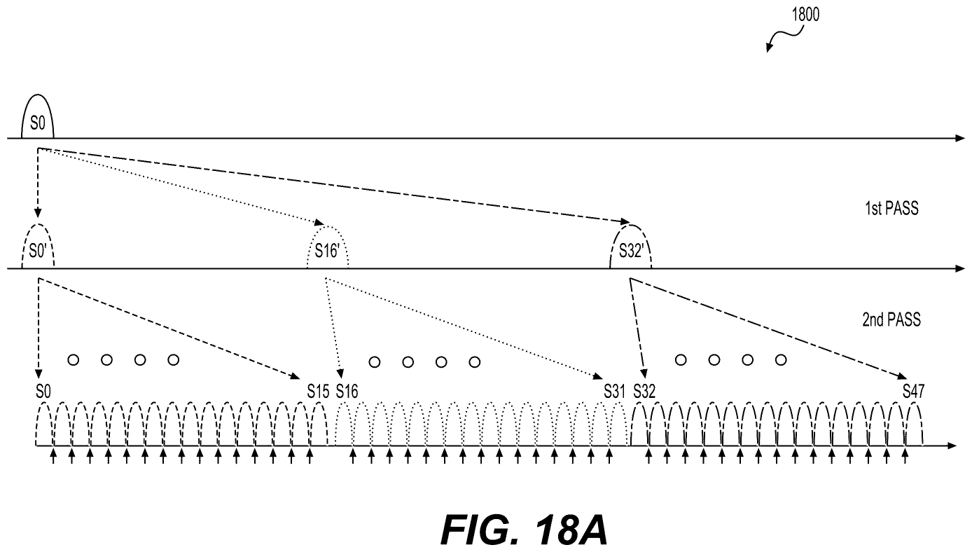

FIG. 18A shows a multi-pass programming process 1800 according to an implementation of the present disclosure. The process 1800 can be performed to program a pair of memory cells in the 11 bits/2 cells storage scheme. The process 1800 is a 3-48 2-pass programming process. Eleven data pages, from page 0 to page 10, are used to program the pair of memory cells. As shown, to program a first cell of the pair of memory cells, a first programming pass is performed. The first memory cell is programmed from an initial level (an erased state) S0 to one of 3 intermediate levels (or states/distributions) S0′, S16′, and S32′. The first programming pass can be based on 3-bits data from page 0, page 1, and page 2. To program a second cell of the pair of memory cells, the first programming pass can be performed similarly based on the same 3-bits data from page 0, page 1, and page 2.

To further program the first memory cell, a second programming pass is performed. The first memory cell is programmed from the intermediate level to one of 48 final levels (or states/distributions) from S0 to S47. The second programming pass can be based on 4-bits data from page 3, page 4, page 5, and page 6. The second programming pass can also be based on the intermediate level which the memory cell previously is programmed in. In one implementation, during the second programming pass, the intermediate level of the memory cell is first read from the memory cell. Respective bits values (e.g., first 2 bits of a 5-bit Gray code in FIG. 13) indicating the intermediate level can be stored in data storage units in a page buffer circuit. Based on the 2 bits indicating the intermediate level and the 4 bits of the second set of 4 data pages (pages 3-6), a target level (one of the 48 final levels) can be determined based on a Gray code. In a similar way, the second programing pass can be performed to further program the second memory cell based on 4-bits data from pages 7-10.

In some implementations, the multi-pass programming pass 1800 may further include a third fine programming pass. During the third programming pass for programing the first or second memory cell, the 48 distributions of memory cells can further be refined. For example, gaps between the distributions can be optimized (for example, broadened), and a larger read margin can be achieved. In such a situation, the process 1800 is a 3-48-48 3-pass programming process.

FIG. 18B shows a timing diagram of a program flow corresponding to the 3-48 2-pass programming process according to an implementation of the present disclosure. Four data transmission periods 1801-1804 are shown along a signal line 1822. Also shown along the signal line 1222 is a page data flow 1821 with an 8-bit data width between a memory controller and a memory device. The signal line 1822 indicates ready/busy (R/B) status of the memory device for receiving page data from the memory controller. As shown, during the first data transmission period 1801, first page data (page 0, page 1, and page 2) with a full-page size of 16 kB are sequentially transmitted from the memory controller to the memory device. Thereafter, a first programming pass to program first memory cells in an even physical page in an even string is performed. The first memory cells are programmed to the 3 intermediate levels (or 3 threshold voltage (Vt) distributions) S0′, S16′, and S32′, shown in FIG. 18A.

During the second data transmission period 1802, the same first page data (page 0, page 1, and page 2) are sequentially transmitted. Thereafter, a first programming pass to program second memory cells in an odd physical page in an odd string is performed. Similarly, the second memory cells are programmed to the 3 intermediate levels (or 3 threshold voltage (Vt) distributions).

During the third data transmission period 1803, second page data (page 3, page 4, page 5, and page 6) are sequentially transmitted. Thereafter, a second programming pass to program first memory cells in the even physical page is performed. The first memory cells are programmed to 48 final levels (or 48 threshold voltage (Vt) distributions). During the fourth data transmission period 1804, third page data (page 7, page 8, page 9, and page 10) are sequentially transmitted. Thereafter, a second programming pass to program second memory cells in the odd physical page is performed. Similarly, the second memory cells are programmed to 48 final levels (or 48 threshold voltage (Vt) distributions).

Page data reception operations 1811-1814 from input pads to a page buffer (PB) are shown below the timing diagram in FIG. 18B. The page data reception operations 1811-1814 correspond to the 4 data transmission periods 1801-1804, respectively. The page data reception operation 1811 includes sequential data receptions of three 16 kB data pages (page 0, page 1, and page 2) at the page buffer for the first-pass programming of the even string. The page data reception operation 1812 includes sequential data receptions of three 16 kB data pages (page 0, page 1, and page 2) at the page buffer for the first-pass programming of the odd string. The page data reception operation 1813 includes sequential data receptions of three 16 kB data pages (pages 3-6) at the page buffer for the second-pass programming of the even string. The page data reception operation 1814 includes sequential data receptions of three 16 kB data pages (pages 7-10) at the page buffer for the second-pass programming of the odd string. In the page data reception operations 1811-1814, full-page data with a size of 16 kB is transmitted. In various implementations of N.5 bits technology, page data may have a full-page size other than 16 kB, such as 8 kB, 32 kB, and the like.

In the programming process of 11 bits/2 cells storage scheme shown in FIG. 18A and FIG. 18B, three data pages (pages 0-2) are programmed in paired memory cells in an even string and an odd string, 4 data pages (pages 3-6) are programmed in the even string, and 4 data pages (pages 7-10) are programmed in the odd string. Accordingly, the data page distribution among the physical pages or strings is represented as 3-4-4.

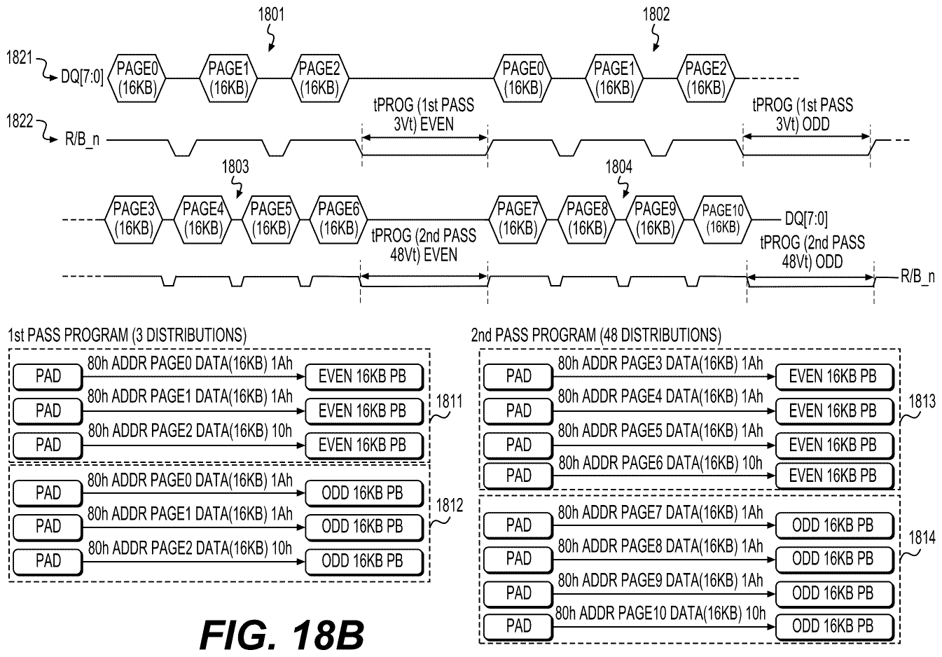

FIG. 19 shows a process 1900 of operating a memory device according to an embodiment of the present disclosure. The process 1900 starts from S1901 and proceeds to S1910.

At S1910, a first row of memory cells in a first string of the memory device are programmed based on a first portion of page data. For example, the memory device can receive a first program command along with the first portion of page data from a memory controller. The first portion of the page data can include 3 data pages (pages 0-2) and be stored in a page buffer. Peripheral circuits of the memory device program the first row of memory cells based on the first portion of page data stored in the page buffer.

At S1920, a second row of memory cells in a second string of the memory device are programmed based on the first portion of the page data. For example, the memory device can receive a second program command along with the first portion of page data from the memory controller. The first portion of the page data can be stored in the page buffer. The peripheral circuits of the memory device program the second row of memory cells based on the first portion of page data stored in the page buffer. In some implementations, the first string and the second string can include an even string and an odd string and belong to a same block and share the same page buffer.

At S1930, the first row of memory cells in the first string of the memory device are programmed based on a second portion of the page data. For example, the memory device can receive a third program command along with the second portion of page data from the memory controller. The second portion of the page data can include multiple data pages and be stored in the page buffer. The peripheral circuits of the memory device program the first row of memory cells based on the second portion of page data stored in the page buffer. Therefore, 2 programming passes are carried out for programming the first row of memory cells.

At S1940, the second row of memory cells in the second string of the memory device are programmed based on a third portion of the page data. For example, the memory device can receive a third program command along with the third portion of page data from the memory controller. The third portion of the page data can include multiple data pages and be stored in the page buffer. The peripheral circuits of the memory device program the second row of memory cells based on the third portion of page data stored in the page buffer. Therefore, 2 programming passes are carried out for programming the second row of memory cells. The process 1900 can proceed to S1999 and terminate at S1999.

In some implementations, only the steps of S1910 and S1920 are performed to program 3 pages of data into the first row of memory cells and the second row of memory cells. For example, in the implementation of 3 bits/2 cells storage scheme, 3 pages of data is programmed into paired strings. The steps of S1930-S1940 can be skipped.

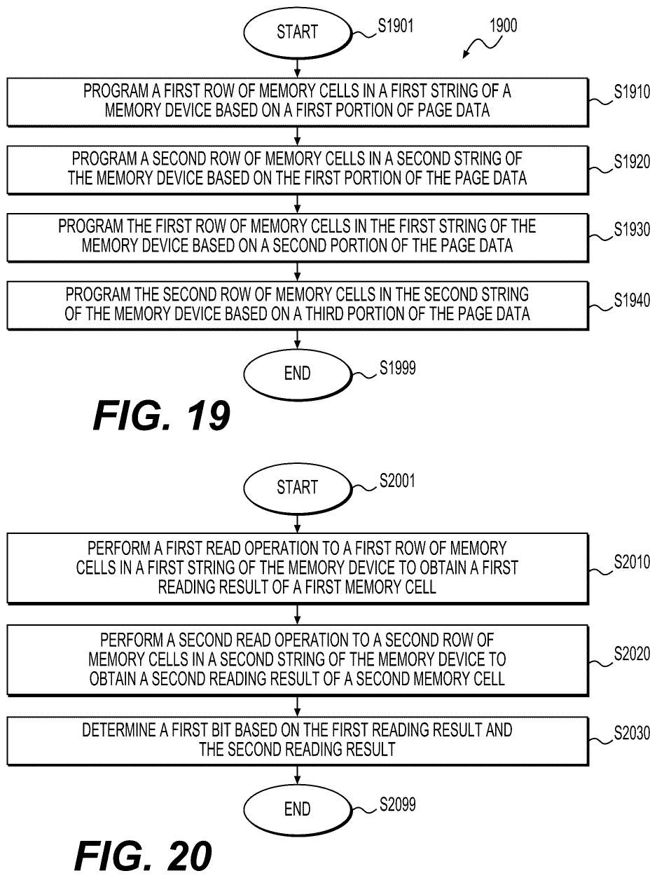

FIG. 20 shows a process 2000 of operating a memory device according to an embodiment of the present disclosure. The process 2000 starts from S2001 and proceeds to S2010.

At S2010, a first read operation to a first row of memory cells in a first string of the memory device is performed to obtain a first reading result of a first memory cell in the first row of memory cells in the first string of the memory device. The first reading result can be stored in a first storage unit of a page buffer circuit.

At S2020, a second read operation to a second row of memory cells in a second string of the memory device is performed to obtain a second reading result of a second memory cell in the second row of memory cells in the second string of the memory device. The second reading result can be stored in a second storage unit of the page buffer circuit.

At S2030, a first bit can be determined based on the first reading result stored in the first storage unit of the page buffer circuit and the second reading result stored in the second storage unit of the page buffer circuit. The process 2000 can proceed to S2099 and terminate at S2099.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A method of operating a memory device, comprising:
programming a first row of memory cells in a first string of the memory device based on a first portion of page data;
programming a second row of memory cells in a second string of the memory device based on the first portion of the page data;
programming the first row of memory cells in the first string of the memory device based on a second portion of the page data; and
programming the second row of memory cells in the second string of the memory device based on a third portion of the page data.

2. The method of claim 1, wherein the first string of the memory device and the second string of the memory device belong to a same block of the memory device and share a page buffer.

3. The method of claim 1, wherein a first memory cell in the first row of memory cells in the first string of the memory device and a second memory cell in the second row of memory cells in the second string of the memory device share a same page buffer circuit via a same bit line.

4. The method of claim 1, wherein the first row of memory cells in the first string of the memory device and the second row of memory cells in the second string of the memory device are controlled by a same word line.

5. The method of claim 1, wherein the page data includes 2N+1 pages, N being an integer greater than 1.

6. The method of claim 1, wherein the first portion of the page data includes 3 pages, the second portion of the page data includes 3 pages, and the third portion of the page data includes 3 pages.

7. The method of claim 6, wherein the programming of the first row of memory cells in the first string of the memory device based on the first portion and the second portion of the page data includes:
performing a first pass of programming to set the first row of memory cells in the first string of the memory device to be in 3 states based on the first 3 pages of the page data; and
performing a second pass of programming to set the first row of memory cells in the first string of the memory device to be in 24 states based on the second 3 pages of the page data.

8. The method of claim 7, wherein the programming of the first row of memory cells in the first string of the memory device based on the first portion and the second portion of the page data is a 3-24-24 multi-pass process and further includes:
performing a third pass of programming to refine the 24 states of the first row of memory cells in the first string of the memory device.

9. The method of claim 1, further comprising:
reading states of the first row of memory cells in the first string of the memory device, wherein the programming the first row of memory cells in the first string of the memory device based on the second portion of the page data is based on the states of the first row of memory cells in the first string of the memory device.

10. A method of operating a memory device, comprising:
performing a first read operation to a first row of memory cells in a first string of the memory device to obtain a first reading result of a first memory cell in the first row of memory cells in the first string of the memory device, the first reading result being stored in a first storage unit of a page buffer circuit;
performing a second read operation to a second row of memory cells in a second string of the memory device to obtain a second reading result of a second memory cell in the second row of memory cells in the second string of the memory device, the second reading result being stored in a second storage unit of the page buffer circuit; and
determining a first bit based on the first reading result stored in the first storage unit of the page buffer circuit and the second reading result stored in the second storage unit of the page buffer circuit.

11. The method of claim 10, wherein a first read voltage is applied to the first row of memory cells in the first string of the memory device during the first read operation, and a second read voltage is applied to the second row of memory cells in the second string of the memory device during the second read operation,
the first read voltage and the second read voltage take one of the following 3 read voltage level combinations:
the first read voltage and the second read voltage both are of a first read voltage level;
the first read voltage has the first read voltage level, and the second read voltage has a second read voltage level; and
the first read voltage has the second read voltage level, and the second read voltage has the first read voltage level, and
corresponding to the 3 read voltage level combinations, 3 different pages are output from the memory device.

12. The method of claim 11, wherein 23 read voltage levels from RL1 to RL23 are used for reading operations in the memory device,
in response to the first read voltage and the second read voltage both using RL8, a first one of the 3 different pages is output from the memory device,
in response to the first read voltage using RL8 and the second read voltage using RL6, a second one of the 3 different pages is output from the memory device, and
in response to the first read voltage using RL16 and the second read voltage using RL8, a third one of the 3 different pages is output from the memory device.

13. The method of claim 12, further comprising:
performing a third read operation to the first row of memory cells in the first string of the memory device to output a second page that is different from a first page that is one of the 3 different pages; and
performing a fourth read operation to the second row of memory cells in the second string of the memory device to output a third page that is different from the first page and the second page.

14. The method of claim 13, wherein depending on different read voltage level combinations, one of 3 different pages is output as the second page during the third read operation.

15. A memory device, comprising:
a block that includes a first string and a second string sharing a page buffer, each string having an array of memory cells having columns of memory cells and rows of memory cells; and
a peripheral circuit coupled to the block and configured to:
program a first row of memory cells in the first string of the memory device based on a first portion of page data;
program a second row of memory cells in the second string of the memory device based on the first portion of the page data;
program the first row of memory cells in the first string of the memory device based on a second portion of the page data; and
program the second row of memory cells in the second string of the memory device based on a third portion of the page data.

16. The memory device of claim 15, wherein the page data includes 2N+1 pages, the first portion of the page data includes 3 pages, the second portion of the page data includes N−1 pages, and the third portion of the page data includes N−1 pages, N being an integer greater than 1.

17. The memory device of claim 15, wherein a first memory cell in the first row of memory cells in the first string of the memory device and a second memory cell in the second row of memory cells in the second string of the memory device share a same page buffer circuit via a same bit line.

18. The memory device of claim 15, wherein the page data includes 9 pages, and the peripheral circuit is configured to:
perform a first pass of programming to set the first row of memory cells in the first string of the memory device to be in 3 states based on the first 3 pages of the page data; and
perform a second pass of programming to set the first row of memory cells in the first string of the memory device to be in 24 states based on the second 3 pages of the page data.

19. The memory device of claim 18, wherein the peripheral circuit is further configured to:
perform a third pass of programming to refine the 24 states of the first row of memory cells in the first string of the memory device.

20. The memory device of claim 15, wherein the peripheral circuit includes a page buffer circuit in the page buffer, the page buffer circuit having a first storage unit, a second storage unit, and a cache storage unit, and
the peripheral circuit is configured to:
perform a first read operation to the first row of memory cells in the first string of the memory device to obtain a first reading result of a first memory cell in the first row of memory cells in the first string of the memory device, the first reading result being stored in the first storage unit;
perform a second read operation to the second row of memory cells in the second string of the memory device to obtain a second reading result of a second memory cell in the second row of memory cells in the second string of the memory device, the second reading result being stored in the second storage unit; and
determine a first bit based on the first reading result stored in the first storage unit and the second reading result stored in the second storage unit, the first bit being stored in the cache storage unit.
